(19) United States
(12) Patent Application Publication
(10) Pub. No.: US 2025/0380491 A1
(43) Pub. Date: Dec. 11, 2025

(54) SEMICONDUCTOR DEVICE

(71) Applicant: ROHM CO., LTD., Kyoto-shi (JP)

(72) Inventors: Kohei MURASAKI, Kyoto-shi (JP); Suguru HONDO, Kyoto-shi (JP)

(73) Assignee: ROHM CO., LTD., Kyoto-shi (JP)

(21) Appl. No.: 19/312,351

(22) Filed: Aug. 28, 2025

Related U.S. Application Data
(63) Continuation of application No. PCT/JP2024/007379, filed on Feb. 28, 2024.

(30) Foreign Application Priority Data
Mar. 17, 2023 (JP) 2023-043545

(51) Int. Cl. H10D 84/00; H10D 8/00; H10D 12/00; H10D 62/10; H10D 62/60

(52) U.S. Cl. CPC H10D 84/161; H10D 8/422; H10D 12/481; H10D 62/103; H10D 62/127; H10D 62/60

(57) ABSTRACT

A semiconductor device includes a semiconductor layer having first and second principal surfaces, an insulated gate bipolar transistor (IGBT) region formed in the semiconductor layer, and a diode region formed adjacent to the IGBT region in a first direction. A plurality of gate trenches are arranged in the IGBT region and extend in a second direction intersecting the first direction. Each trench includes a gate conductive layer embedded through a gate insulating layer, and unit cells are defined between adjacent trenches. An emitter region is formed on the first principal surface of each unit cell. The emitter region of a unit cell located closer to the diode region has a smaller area than the emitter region of a unit cell located farther from the diode region.

### CROSS-REFERENCE TO RELATED APPLICATIONS

The present application is a bypass continuation of International Application No. PCT/JP2024/007379, filed Feb. 28, 2024, which corresponds to Japanese Patent Application No. 2023-043545, filed on Mar. 17, 2023, in the Japan Patent Office, and the entire disclosure of these applications are incorporated herein by reference.

### TECHNICAL FIELD

The present disclosure relates to a semiconductor device including an IGBT region and a diode region.

### BACKGROUND ART

Patent Literature (WO 2020/080476 A) discloses a reverse conducting-insulated gate bipolar transistor (RC-IGBT) as an example of a semiconductor device. The RC-IGBT includes an IGBT region and a diode region built into a common semiconductor layer. The IGBT region includes an IGBT. The diode region includes a diode.

### BRIEF DESCRIPTION OF DRAWINGS

FIG. 1 is a schematic plan view of a semiconductor device according to a first preferred embodiment of the present disclosure.

FIG. 2 is a plan view schematically illustrating a structure of a first principal surface of the semiconductor device.

FIG. 3 is an enlarged view of a portion surrounded by an alternate long and short dashed line III in FIG. 1.

FIG. 4 is an enlarged view of a portion surrounded by an alternate long and short dashed line IV in FIG. 3.

FIG. 5 is an enlarged view of a portion surrounded by an alternate long and short dashed line V in FIG. 4.

FIG. 6 is an enlarged view of a portion surrounded by an alternate long and short dashed line VI in FIG. 4.

FIG. 7A is an enlarged view of a portion surrounded by an alternate long and short dashed line VIIA in FIG. 4.

FIG. 7B is an enlarged view of a portion surrounded by an alternate long and short dashed line VIIB in FIG. 4.

FIG. 8 is a cross-sectional view taken along line VIII-VIII in FIG. 7A.

FIG. 9 is a cross-sectional view taken along line IX-IX in FIG. 7A.

FIG. 10 is a cross-sectional view taken along line X-X in FIG. 7A.

FIG. 11 is a cross-sectional view taken along line XI-XI in FIG. 5.

FIG. 12 is a cross-sectional view of a semiconductor device according to a second preferred embodiment of the present disclosure.

FIG. 13 is an enlarged view of a semiconductor device according to a third preferred embodiment of the present disclosure, and is a view corresponding to FIG. 7A.

FIG. 14 is a cross-sectional view taken along line XIV-XIV shown in FIG. 13.

FIG. 15 is an enlarged view of a semiconductor device according to a fourth preferred embodiment of the present disclosure, and is a view corresponding to FIG. 4.

FIG. 16 is an enlarged view of a portion surrounded by an alternate long and short dashed line XVI in FIG. 15.

FIG. 17 is an enlarged view of a portion surrounded by an alternate long and short dashed line XVII in FIG. 15.

FIG. 18 is a cross-sectional view taken along line XVIII-XVIII in FIG. 16.

FIG. 19 is a cross-sectional view taken along line XIX-XIX in FIG. 16.

### DESCRIPTION OF EMBODIMENTS

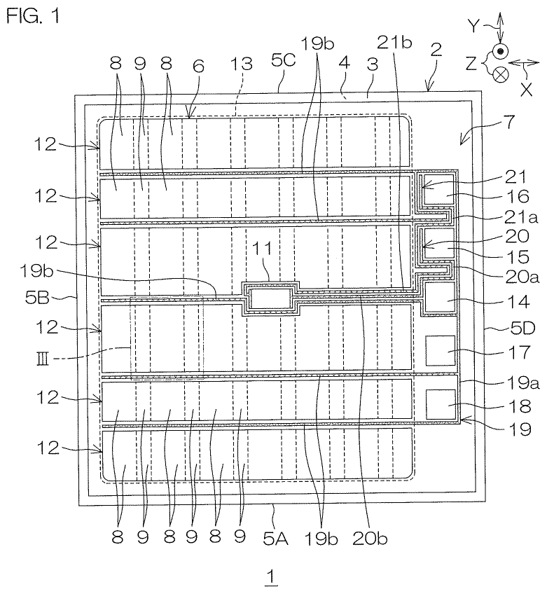

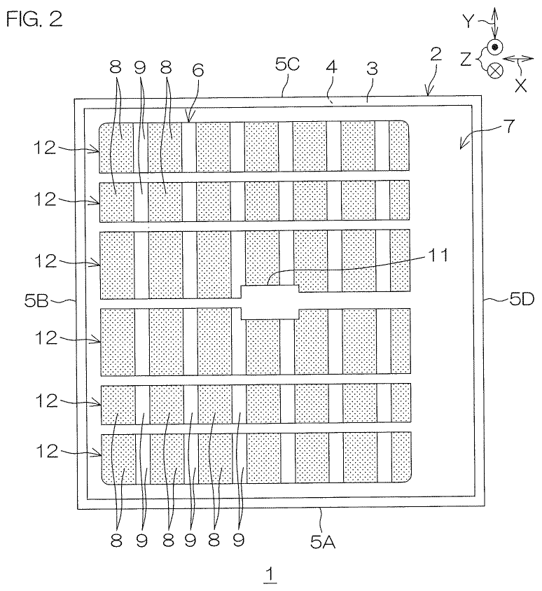

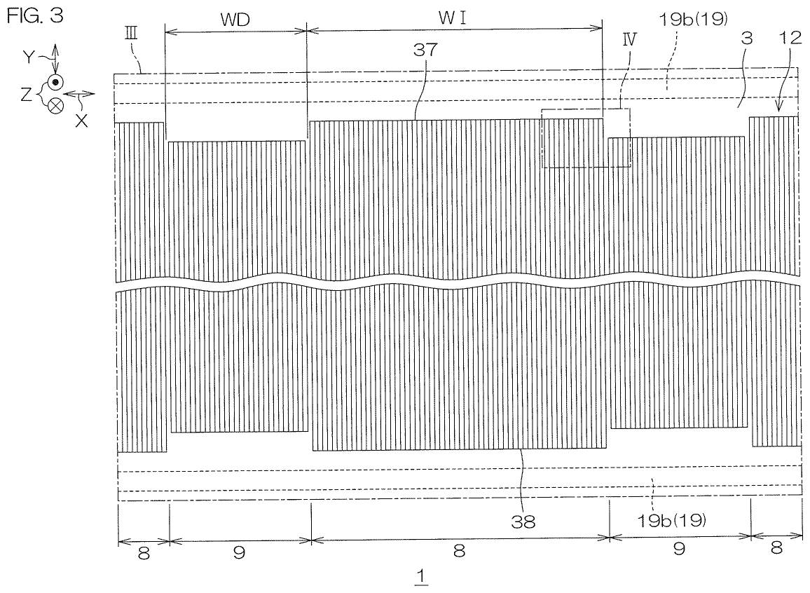

FIG. 1 is a schematic plan view of a semiconductor device 1 according to a first preferred embodiment of the present disclosure. FIG. 2 is a plan view schematically illustrating a structure of a first principal surface 3 of the semiconductor device 1. FIG. 3 is an enlarged view of a portion surrounded by an alternate long and short dashed line III in FIG. 1.

The semiconductor device 1 is an electronic component having a reverse conducting-insulated gate bipolar transistor (RC-IGBT) integrally including an IGBT and a diode.

Referring to FIGS. 1 and 2, the semiconductor device 1 includes a semiconductor layer 2 of rectangular parallelepiped shape. The semiconductor layer 2 has a first principal surface 3 at one side, a second principal surface 4 at another side, and side surfaces 5A, 5B, 5C, and 5D connecting the first principal surface 3 and the second principal surface 4.

The first principal surface 3 and the second principal surface 4 are each formed in a quadrangle shape in a plan view as viewed in a normal direction Z thereto (hereinafter, simply referred to as “plan view”). The side surface 5A and the side surface 5C extend in a first direction X and oppose each other in a second direction Y intersecting the first direction X. The side surface 5B and the side surface 5D extend in a second direction Y and oppose each other in the first direction X. Specifically, the second direction Y is orthogonal to the first direction X.

The semiconductor layer 2 includes an active region 6 and an outer region 7. The active region 6 is a region where an RC-IGBT is formed. In a plan view, the active region 6 is set at a central portion of the semiconductor layer 2 at intervals toward an inner region from the side surfaces 5A to 5D. In a plan view, the active region 6 may be set to a quadrilateral shape having four sides parallel to the side surfaces 5A to 5D. A thickness of the semiconductor layer 2 may be 50 μm or more and 200 μm or less.

The outer region 7 is a region at an outer side of the active region 6. The outer region 7 extends in a band shape along a peripheral edge of the active region 6 in a plan view. Specifically, the outer region 7 has an endless shape (a quadrilateral annular shape) surrounding the active region 6 in a plan view.

The active region 6 includes an IGBT region 8 and a diode region 9. In FIG. 2, the IGBT region 8 is shown with hatching for clarity. The IGBT region 8 is a region where an IGBT is formed. The diode region 9 is a region where a diode is formed. The diode region 9 is adjacent to the IGBT region 8.

The active region 6 specifically includes an RC-IGBT array 12. A plurality of (six in this preferred embodiment) RC-IGBT arrays 12 are formed at intervals in the second direction Y. The RC-IGBT array 12 has a first end portion on one side (side surface 5B side) and a second end portion on the other side (side surface 5D side).

The RC-IGBT array 12 has a loop array repeatedly including the IGBT region 8, the diode region 9, the IGBT region 8, the diode region 9 . . . arranged in a line along the first direction X from the first end portion toward the second end portion. The first end portion of the RC-IGBT array 12 is formed by the IGBT region 8 in this preferred embodiment. The first end portion of the RC-IGBT array 12 may be formed by the diode region 9. The second end portion of the RC-IGBT array 12 is formed by the IGBT region 8 in this preferred embodiment. The second end portion of the RC-IGBT array 12 may be formed by the diode region 9.

In the active region 6, a plurality of IGBT regions 8 are dispersedly arranged. The plurality of IGBT regions 8 are formed at intervals along the first direction X and the second direction Y. In this preferred embodiment, the plurality of IGBT regions 8 are disposed in a matrix in a plan view. The plurality of IGBT regions 8 oppose each other along the first direction X and oppose each other along the second direction Y. Specifically, each of the plurality of IGBT regions 8 is formed in a rectangular shape extending along the second direction Y.

Moreover, in the active region 6, a plurality of diode regions 9 are dispersedly arranged. Specifically, each of the plurality of diode regions 9 is formed such as to be adjacent to the IGBT region 8 in the first direction X. The plurality of diode regions 9 are formed at intervals along the first direction X and the second direction Y. In this preferred embodiment, the plurality of diode regions 9 are arranged in a matrix in a plan view. The plurality of diode regions 9 oppose each other along the first direction X and oppose each other along the second direction Y. Specifically, each of the plurality of diode regions 9 is formed in a rectangular shape extending along the second direction Y. A planar area of each diode region 9 may be equal to or smaller than a planar area of each IGBT region 8. The planar area of each diode region 9 is preferably less than the planar area of each IGBT region 8.

Referring to FIG. 3, a width WI of each IGBT region 8 may be 10 μm or more and 1000 μm or less. The width WI may be 100 μm or more. The width WI is preferably 200 μm or more.

A width WD of each diode region 9 may be equal to or smaller than the width WI of each IGBT region 8. The width WD is a width of the diode region 9 in the first direction X. The width WD of each diode region 9 is preferably less than the width WI of each IGBT region 8.

Referring to FIGS. 1 and 2, the active region 6 further includes a sensor region 11 in which a temperature sensor is formed. The sensor region 11 is formed in a region between two RC-IGBT arrays 12 adjacent to each other in the second direction Y. The sensor region 11 is formed at the central portion of the active region 6 in this preferred embodiment.

The semiconductor device 1 further includes an emitter terminal electrode 13 (see a broken line portion in FIG. 1). The emitter terminal electrode 13 is formed on the first principal surface 3 of the semiconductor layer 2 in the active region 6. The emitter terminal electrode 13 transmits an emitter signal to the active region 6 (IGBT region 8). The emitter signal may be a reference potential or a ground potential.

The semiconductor device 1 further includes a plurality of (five in this preferred embodiment) terminal electrodes 14, 15, 16, 17, and 18 formed on the first principal surface 3 of the semiconductor layer 2 in the outer region 7. The plurality of terminal electrodes 14 to 18 are arranged at intervals along the side surface 5D. The plurality of terminal electrodes 14 to 18 are formed in a quadrangular shape in a plan view.

The plurality of terminal electrodes 14 to 18 include, in this preferred embodiment, a gate terminal electrode 14, a first sense terminal electrode 15, a second sense terminal electrode 16, a current detection terminal electrode 17, and an open terminal electrode 18. The gate terminal electrode 14 transmits a gate signal to the active region 6 (IGBT region 8). The first sense terminal electrode 15 and the second sense terminal electrode 16 transmit a control signal for controlling the sensor region 11 (temperature sensor). The current detection terminal electrode 17 is an electrode for detecting a current flowing through the active region 6 and extracting the current to the outside. The open terminal electrode 18 is electrically floating. The gate terminal electrode 14, the first sense terminal electrode 15, the second sense terminal electrode 16, the current detection terminal electrode 17, and the open terminal electrode 18 are arranged randomly. In this preferred embodiment, the open terminal electrode 18, the current detection terminal electrode 17, the gate terminal electrode 14, the first sense terminal electrode 15, and the second sense terminal electrode 16 are arranged in this order from the side surface 5A side toward the side surface 5C side.

The semiconductor device 1 further includes a gate wiring 19 electrically connected to the gate terminal electrode 14. The gate wiring 19 is also referred to as a gate finger. The gate wiring 19 extends from the outer region 7 toward the active region 6. The gate wiring 19 transmits the gate signal applied to the gate terminal electrode 14 to the active region 6 (IGBT region 8). Specifically, the gate wiring 19 includes a first region 19a located in the outer region 7 and a second region 19b located in the active region 6. The first region 19a is electrically connected to the gate terminal electrode 14. In this preferred embodiment, the first region 19a is selectively routed in a region on the side surface 5D side in the outer region 7.

A plurality of (five in this preferred embodiment) second regions 19b are formed in the active region 6. The plurality of second regions 19b are formed at intervals along the second direction Y. Each of the plurality of second regions 19b is formed in a region between two adjacent RC-IGBT arrays 12. The plurality of second regions 19b extend from a region on the side surface 5D side toward a region on the side surface 5B side in the outer region 7. The plurality of second regions 19b are continuous with the first region 19a in the outer region 7. The plurality of second regions 19b transmit the gate signal to any one or both of the two RC-IGBT arrays 12 adjacent to each other.

The gate signal applied to the gate terminal electrode 14 is transmitted to the second region 19b through the first region 19a. Accordingly, the gate signal is transmitted to the active region 6 (IGBT region 8) through the second region 19b.

A first sense wiring 20 is electrically connected to the first sense terminal electrode 15. The first sense wiring 20 extends from the outer region 7 toward the sensor region 11. The first sense wiring 20 transmits a control signal of the temperature sensor. Specifically, the first sense wiring 20 includes a first region 20a located in the outer region 7 and a second region 20b located in the active region 6. The first region 20a is electrically connected to the first sense terminal electrode 15. The second region 20b is electrically connected to the temperature sensor in the sensor region 11. The second region 20b is continuous with the first region 20a in the outer region 7. An electric signal applied to the first sense terminal electrode 15 is transmitted to the second region 20b through the first region 20a. Accordingly, the electric signal is transmitted to the temperature sensor through the second region 20b.

A second sense wiring 21 is electrically connected to the second sense terminal electrode 16. The second sense wiring 21 extends from the outer region 7 toward the sensor region 11. The second sense wiring 21 transmits a control signal of the temperature sensor. Specifically, the second sense wiring 21 includes a first region 21a located in the outer region 7 and a second region 21b located in the active region 6. The first region 21a is electrically connected to the second sense terminal electrode 16. The second region 21b is electrically connected to the temperature sensor in the sensor region 11. The second region 21b is continuous with the first region 21a in the outer region 7. An electric signal applied to the second sense terminal electrode 16 is transmitted to the second region 21b through the first region 21a. Accordingly, the electric signal is transmitted to the temperature sensor through the second region 21b.

The gate wiring 19, the first sense wiring 20, and the second sense wiring 21 are formed in the region where the sensor region 11 is formed in the region between the plurality of RC-IGBT arrays 12 adjacent to each other. The gate wiring 19, the first sense wiring 20, and the second sense wiring 21 run in parallel in the region between two adjacent RC-IGBT arrays 12.

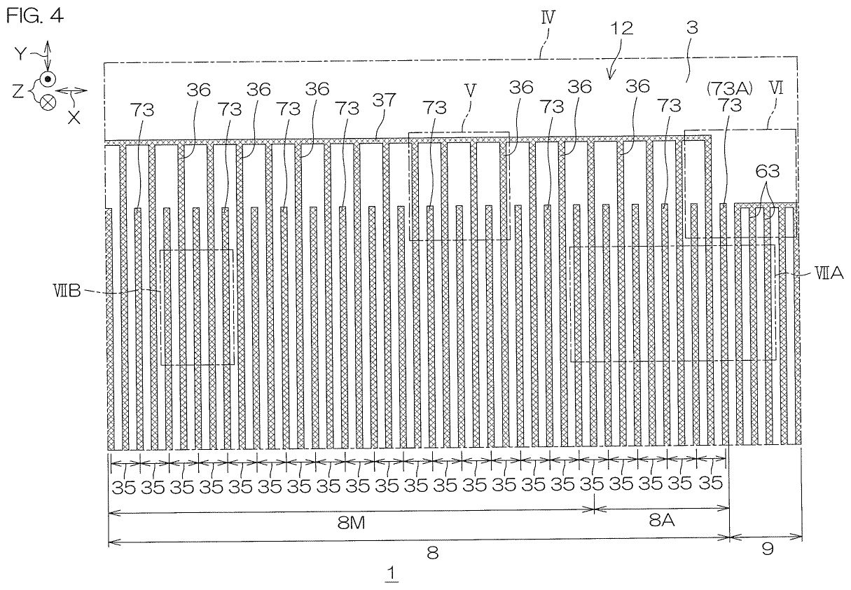

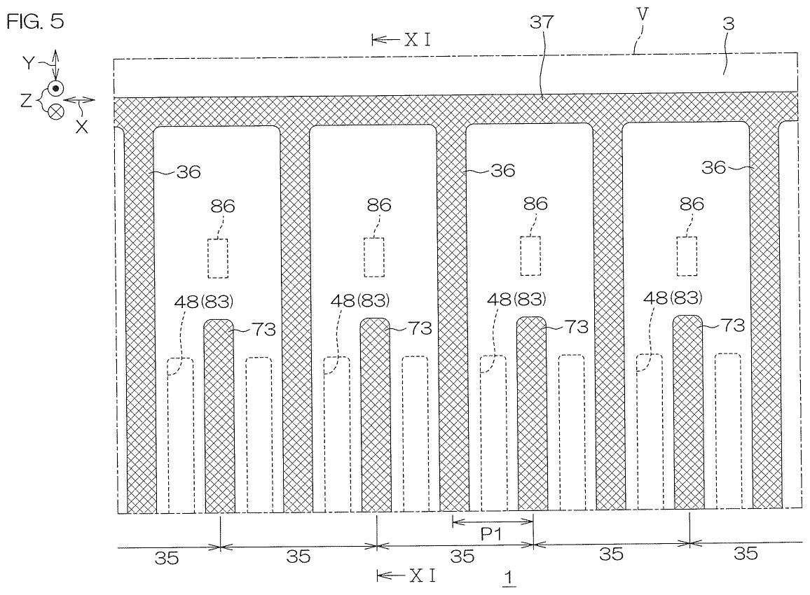

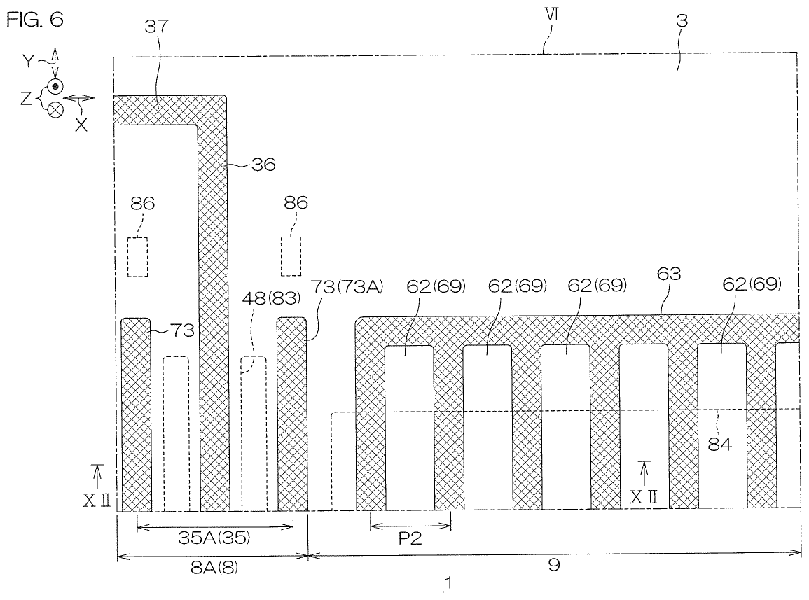

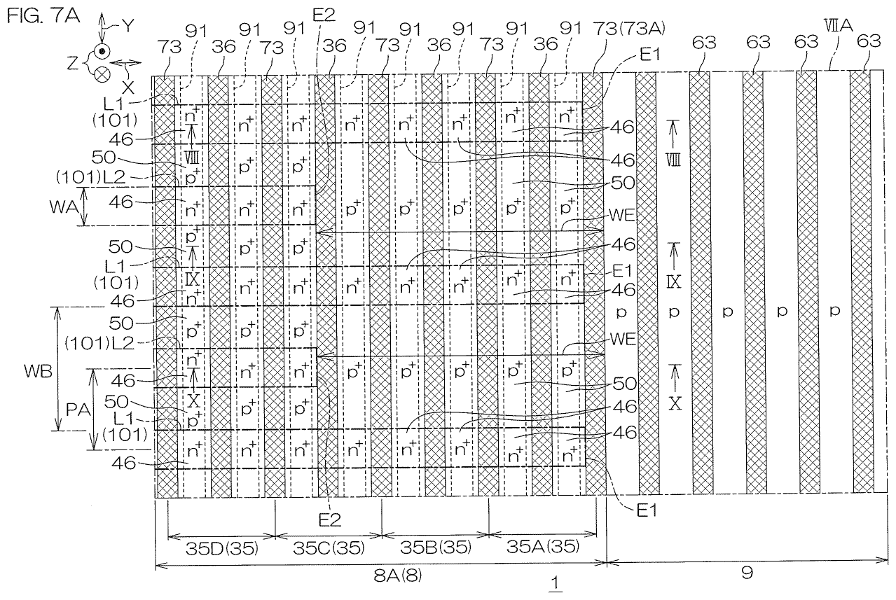

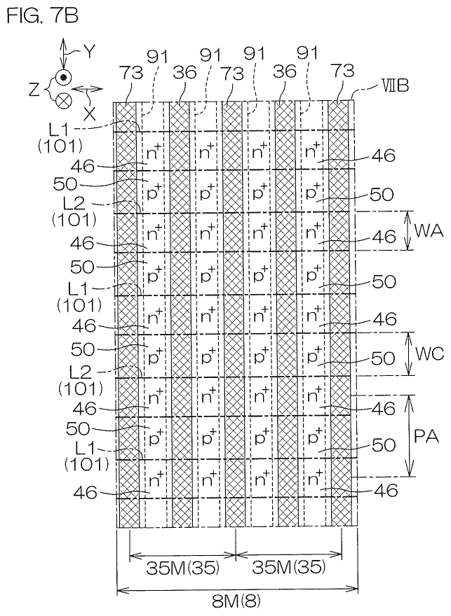

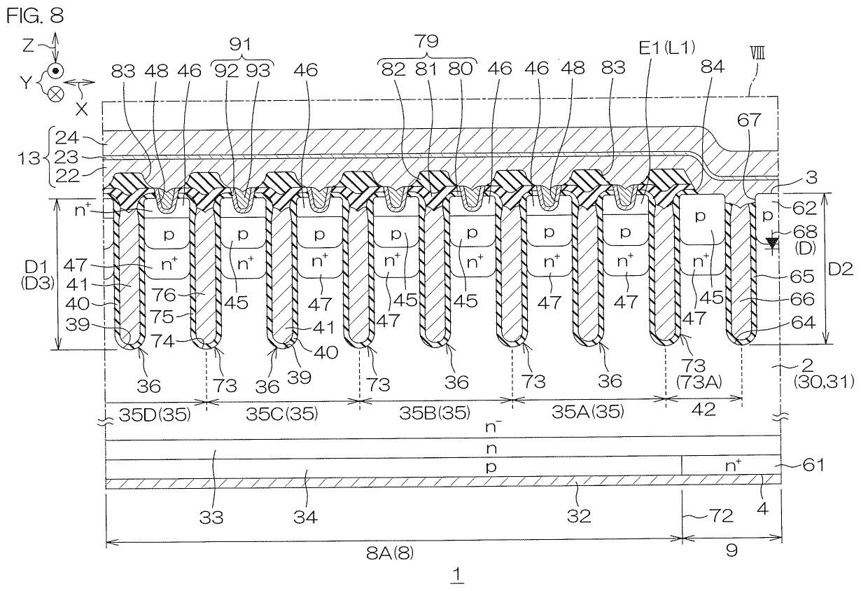

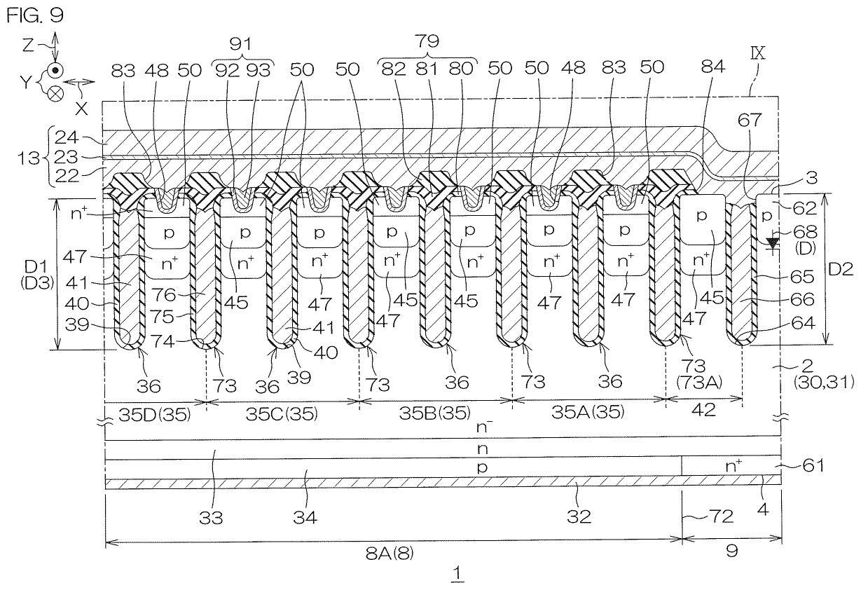

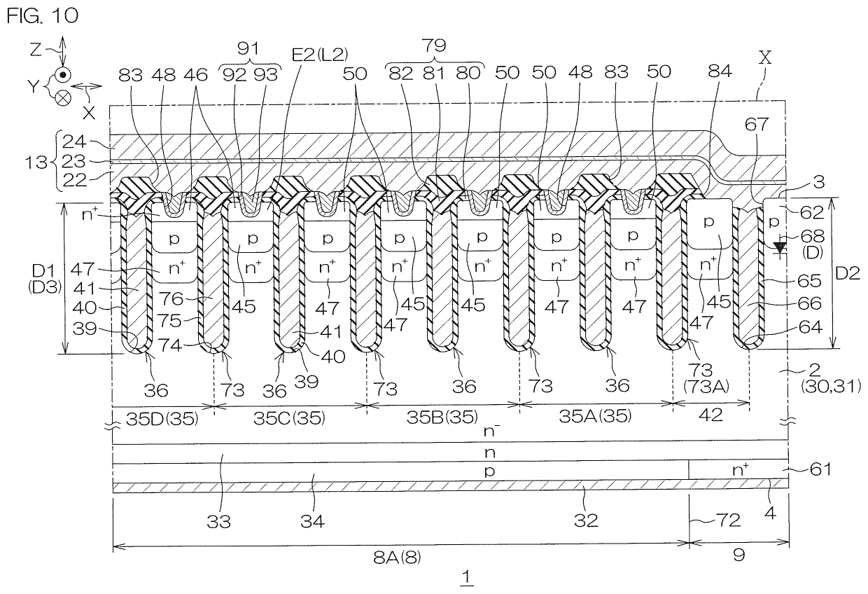

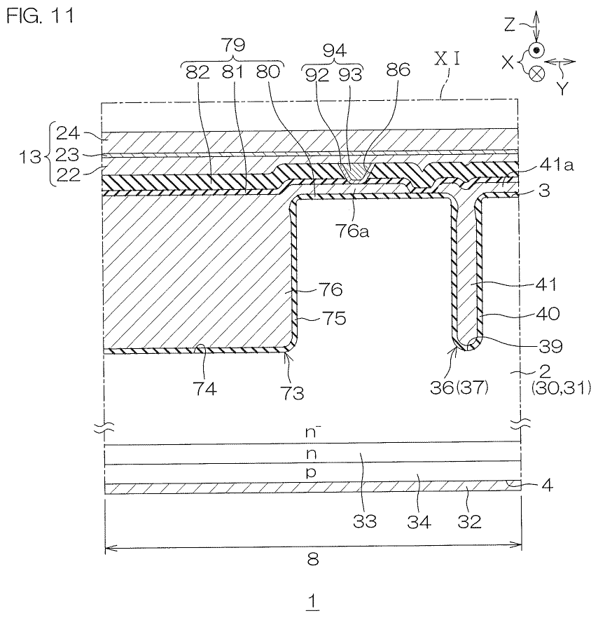

FIG. 4 is an enlarged view of a portion surrounded by an alternate long and short dashed line IV in FIG. 3. FIG. 5 is an enlarged view of a portion surrounded by an alternate long and short dashed line V in FIG. 4. FIG. 6 is an enlarged view of a portion surrounded by an alternate long and short dashed line VI in FIG. 4. FIG. 7A is an enlarged view of an internal structure of a portion surrounded by an alternate long and short dashed line VIIA in FIG. 4. FIG. 7B is an enlarged view of an internal structure of a portion surrounded by an alternate long and short dashed line VIIB in FIG. 4. FIG. 8 is a cross-sectional view taken along line VIII-VIII in FIG. 7A. FIG. 9 is a cross-sectional view taken along line IX-IX in FIG. 7A. FIG. 10 is a cross-sectional view taken along line X-X in FIG. 7A. FIG. 11 is a cross-sectional view taken along line XI-XI in FIG. 5.

Referring to FIGS. 8 to 11, the semiconductor device 1 further includes an n⁻-type drift region 30 formed inside the semiconductor layer 2. The drift region 30 is, specifically, formed in an entire area of the semiconductor layer 2 in the first direction X and in the second direction Y. The drift region 30 is formed at a surface layer portion of the first principal surface 3 of the semiconductor layer 2 in the normal direction Z (thickness direction of the semiconductor layer 2). An n-type (first conductivity type) impurity concentration of the drift region 30 may be 1.0×10¹³ cm⁻³ or more and 1.0×10¹⁵ cm⁻³ or less.

In this preferred embodiment, the semiconductor layer 2 has a single-layered structure including an n⁻-type semiconductor substrate 31. The semiconductor substrate 31 may be a silicon-made FZ substrate that is formed by a floating zone (FZ) method. The drift region 30 is formed by the semiconductor substrate 31.

The semiconductor device 1 includes a collector terminal electrode 32 formed on the second principal surface 4 of the semiconductor layer 2. The collector terminal electrode 32 is electrically connected to the second principal surface 4. Specifically, the collector terminal electrode 32 is electrically connected to the IGBT region 8 (collector region 34 to be described later) and the diode region 9 (cathode region 61 to be described later).

The collector terminal electrode 32 forms an ohmic contact with the second principal surface 4. The collector terminal electrode 32 transmits a collector signal to the IGBT region 8 and the diode region 9. The collector terminal electrode 32 may include at least one among a Ti layer, an Ni layer, an Au layer, an Ag layer, and an Al layer. The collector terminal electrode 32 may have a single-layered structure that includes a Ti layer, an Ni layer, an Au layer, an Ag layer, or an Al layer. The collector terminal electrode 32 may have a laminated structure in which at least two among a Ti layer, an Ni layer, an Au layer, an Ag layer, and an Al layer are laminated randomly.

The semiconductor device 1 includes an n-type buffer layer 33 that is formed at a surface layer portion of the second principal surface 4 of the semiconductor layer 2. The buffer layer 33 may be formed in an entire area of the surface layer portion of the second principal surface 4. An n-type impurity concentration of the buffer layer 33 is higher than the n-type impurity concentration of the drift region 30. The n-type impurity concentration of the buffer layer 33 may be 1.0×10¹⁵ cm⁻³ or more and 1.0×10¹⁷ cm⁻³ or less A thickness of the buffer layer 33 may be not less than 0.5 μm and not more than 30 μm.

Each IGBT region 8 includes a p-type (second conductivity type) collector region 34 formed in a surface layer portion of the second principal surface 4 of the semiconductor layer 2. The collector region 34 is exposed from the second principal surface 4. The collector region 34 may be formed in an entire area of the IGBT region 8 at the surface layer portion of the second principal surface 4. A p-type impurity concentration of the collector region 34 may be 1.0×10¹⁵ cm⁻³ or more and 1.0×10¹⁸ cm⁻³ or less. The collector region 34 forms an ohmic contact with the collector terminal electrode 32.

Referring to FIGS. 4 to 11, each IGBT region 8 includes a plurality of FET structures 35 as unit cells formed on the first principal surface 3 of the semiconductor layer 2. Specifically, the FET structure 35 includes a first trench gate structure 36 that is formed in the first principal surface 3. The FET structure 35 is defined between the adjacent first trench gate structures 36 (between the adjacent first gate trenches 39). The plurality of first trench gate structures 36 are formed in the IGBT region 8 at an interval along the first direction X. A distance between two first trench gate structures 36 that are adjacent to each other in the first direction X may be not less than 1 μm and not more than 8 μm. In FIGS. 4 to 7B, the first trench gate structure 36 is indicated by hatching.

The plurality of first trench gate structures 36 are formed in a band shape extending along the second direction Y in a plan view. The plurality of first trench gate structures 36 are formed as a whole in a stripe pattern. The plurality of first trench gate structures 36 each have one end portion at one side in the second direction Y and the other end portion at the other side in the second direction Y.

Referring to FIG. 3, the first trench gate structure 36 includes a first outer trench gate structure 37 and a second outer trench gate structure 38. The first outer trench gate structure 37 extends along the first direction X and connects one end portions of the plurality of first trench gate structures 36. The second outer trench gate structure 38 extends along the first direction X and connects other end portions of the plurality of first trench gate structures 36.

The first outer trench gate structure 37 and the second outer trench gate structure 38 have the same structure as the first trench gate structure 36 except that extending directions are different. Hereinafter, a structure of the first trench gate structure 36 will be described, and the description of structures of the first outer trench gate structure 37 and the second outer trench gate structure 38 will be omitted.

Referring to FIGS. 8 to 11, each first trench gate structure 36 includes a first gate trench (gate trench) 39, a first gate insulating layer (gate insulating layer) 40, and a first gate conductive layer (gate conductive layer) 41. The first gate trench 39 is formed in the first principal surface 3. The first gate trench 39 includes a side wall and a bottom wall. The side wall of the first gate trench 39 may be formed perpendicular with respect to the first principal surface 3.

The side wall of the first gate trench 39 may be inclined downwardly from the first principal surface 3 to the bottom wall. The first gate trench 39 may be formed in a tapered shape in which an opening area at an opening side is larger than a bottom area. The bottom wall of the first gate trench 39 may be formed parallel to the first principal surface 3. The bottom wall of the first gate trench 39 may be formed in a curved shape toward the second principal surface 4. The first gate trench 39 includes a bottom wall edge portion. The bottom wall edge portion connects the side wall and the bottom wall of the first gate trench 39. The bottom wall edge portion may be formed in a curved shape toward the second principal surface 4.

A depth D1 of the first gate trench 39 may be 2 μm or more and 10 μm or less. The depth D1 of the first gate trench 39 may be defined as a distance between a depth position of the deepest portion of the bottom wall of the first gate trench 39 and the first principal surface 3. A width of the first gate trench 39 may be 0.5 μm or more and 3 μm or less. The width of the first gate trench 39 is a width of the first gate trench 39 in the first direction X.

The first gate insulating layer 40 is formed in a film shape along an inner wall of the first gate trench 39. The first gate insulating layer 40 defines a recessed space inside the first gate trench 39. In this preferred embodiment, the first gate insulating layer 40 includes a silicon oxide film. The first gate insulating layer 40 may include a silicon nitride film in place of, or in addition to the silicon oxide film.

The first gate conductive layer 41 is embedded in the first gate trench 39 across the first gate insulating layer 40. Specifically, the first gate conductive layer 41 is embedded in a recessed space that is defined by the first gate insulating layer 40 in the first gate trench 39. The first gate conductive layer 41 is controlled by the gate signal. The first gate conductive layer 41 may contain a conductive polysilicon.

The first gate conductive layer 41 is formed in a wall shape extending along the normal direction Z in a cross-sectional view. The first gate electrode layer 41 has an upper end portion that is positioned at the opening side of the first gate trench 39. The upper end portion of the first gate conductive layer 41 is positioned at the bottom wall side of the first gate trench 39 with respect to the first principal surface 3.

A recess which is recessed toward the bottom wall of the first gate trench 39 is formed at the upper end portion of the first gate conductive layer 41. The recess at the upper end portion of the first gate conductive layer 41 is formed in a tapered shape toward the bottom wall of the first gate trench 39. The upper end portion of the first gate conductive layer 41 has a constricted portion constricted inside the first gate conductive layer 41.

Referring to FIGS. 8 to 10, the FET structure 35 includes a p-type body region 45 formed in the surface layer portion of the first principal surface 3 of the semiconductor layer 2. A p-type impurity concentration of the body region 45 may be 1.0×10¹⁷ cm⁻³ or more and 1.0×10¹⁸ cm⁻³ or less. The body regions 45 are each formed at the both sides of the first trench gate structure 36. The body region 45 is formed in a band shape extending along the first trench gate structure 36 in a plan view. The body region 45 is exposed from the side wall of the first gate trench 39. A bottom portion of the body region 45 is formed in a region between the first principal surface 3 and the bottom wall of the first gate trench 39 with respect to the normal direction Z.

The FET structure 35 includes a plurality of n⁺-type emitter regions 46 formed on the first principal surface 3 of the IGBT region 8 and a plurality of p⁺-type contact regions 50 formed on the first principal surface 3. The emitter region 46 and the contact region 50 are formed in a surface layer portion of the body region 45.

Referring to FIGS. 8 and 10, the emitter regions 46 are formed on both sides of the first trench gate structure 36. An n-type impurity concentration of the emitter region 46 is higher than the n-type impurity concentration of the drift region 30. The n-type impurity concentration of the emitter region 46 may be 1.0×10¹⁹ cm⁻³ or more and 1.0×10²⁰ cm⁻³ or less. The emitter region 46 is in contact with the body region 45 from the normal direction Z. The emitter region 46 is exposed from the side wall of the first gate trench 39. A bottom portion of the emitter region 46 is formed in a region between the upper end portion of the first gate conductive layer 41 and the bottom portion of the body region 45 with respect to the normal direction Z.

Referring to FIGS. 9 and 10, the contact regions 50 are formed on both sides of the first trench gate structure 36. A p-type impurity concentration of the contact region 50 is higher than the p-type impurity concentration of the body region 45. The p-type impurity concentration of the contact region 50 may be 1.0×10¹⁹ cm⁻³ or more and 1.0×10²⁰ cm⁻³ or less. The contact region 50 is in contact with the body region 45 from the normal direction Z. The contact region 50 is exposed from the side wall of the first gate trench 39. A bottom portion of the contact region 50 is formed in a region between the upper end portion of the first gate conductive layer 41 and the bottom portion of the body region 45 with respect to the normal direction Z.

Referring to FIGS. 7A and 7B, each FET structure 35 includes a plurality of n⁺-type emitter regions 46 and a plurality of p⁺-type contact regions 50. On both sides of the first trench gate structure 36, the plurality of emitter regions 46 and the plurality of contact regions 50 are alternately formed in the second direction Y. The plurality of emitter regions 46 are formed at intervals WA or intervals WB in the second direction Y on both sides of the first trench gate structure 36. The plurality of contact regions 50 are formed at intervals in the second direction Y on both sides of the first trench gate structure 36. The contact region 50 is in contact with the emitter region 46 adjacent in the second direction Y.

Referring to FIGS. 8 to 10, the FET structure 35 further includes an n⁺-type carrier storage region 47 formed in a region on the second principal surface 4 side with respect to the body region 45 in the semiconductor layer 2. The carrier storage region 47 is in contact with the body region 45 from the normal direction Z. The carrier storage region 47 is formed in a band shape extending along the first trench gate structure 36 in a plan view. A bottom portion of the carrier storage region 47 is formed in a region between the bottom portion of the body region 45 and the bottom wall of the gate trench 39 with respect to the normal direction Z. An n-type impurity concentration of the carrier storage region 47 may be 1.0×10¹⁵ cm⁻³ or more and 1.0×10¹⁷ cm⁻³ or less.

The FET structure 35 further includes a contact trench 48 formed in the first principal surface 3 of the semiconductor layer 2. In this preferred embodiment, the FET structure 35 includes the plurality of contact trenches 48 that are formed at both sides of the first trench gate structure 36. The contact trench 48 exposes the emitter region 46 and the contact region 50. The contact trench 48 does not penetrate through the emitter region 46 and the contact region 50. A bottom portion of the contact trench 48 is in contact with the emitter region 46 and the contact region 50.

The contact trench 48 is formed at an interval from the first trench gate structure 36 in the first direction X. The contact trench 48 extends in a band shape along the first trench gate structure 36 in a plan view. In the second direction Y, a length of the contact trench 48 is equal to or less than a length of the first trench gate structure 36. Specifically, the length of the contact trench 48 is less than the length of the first trench gate structure 36.

As described so far, in the FET structure 35, the first gate conductive layer 41 opposes the body region 45 and the emitter region 46 across the first gate insulating layer 40. In this preferred embodiment, the first gate conductive layer 41 also opposes the carrier storage region 47 across the first gate insulating layer 40. A channel of the IGBT is formed in a region between the emitter region 46 and the drift region 30 (carrier storage region 47) in the body region 45. On/off of the channel is controlled by the gate signal.

Each IGBT region 8 further includes an emitter trench structure 73 formed on the first principal surface 3 of the semiconductor layer 2. Each IGBT region 8 specifically includes a plurality of emitter trench structures 73 formed on either side of the FET structure 35. The emitter trench structure 73 is formed in a region adjacent to the FET structure 35 at the surface layer portion of the first principal surface 3. The emitter trench structure 73 is formed in a band shape extending along the second direction Y in a plan view. The plurality of emitter trench structures 73 are formed in a stripe pattern as a whole. The emitter trench structure 73 may be in a band shape parallel to the first trench gate structure 36.

Referring to FIGS. 4 and 5, in each IGBT region 8, the first trench gate structures 36 and the emitter trench structures 73 are alternately arranged at intervals along the first direction X. The first trench gate structure 36 and the emitter trench structure 73 may be arrayed alternately, with an equal interval kept. A distance (first pitch P1 (see FIG. 5)) between the two first trench gate structures 36 and the emitter trench structure 73 adjacent to each other in the first direction X may be, for example, 1.0 μm or more and 3.5 μm or less.

With reference to FIGS. 8 to 10, the emitter trench structure 73 includes an emitter trench 74, an emitter insulating layer 75 and an emitter potential electrode layer 76. The emitter trench 74 is formed in the first principal surface 3 of the semiconductor layer 2. The emitter trench 74 includes a side wall and a bottom wall. The side wall of the emitter trench 74 may be formed perpendicular to the first principal surface 3.

The side wall of the emitter trench 74 may be inclined downwardly from the first principal surface 3 toward the bottom wall. The emitter trench 74 may be formed in a tapered shape in which an opening area at the opening side is larger than a bottom area. The emitter region 46, the body region 45 and the carrier storage region 47 are exposed from a side wall (outer side wall) that faces the FET structure 35 in the emitter trench 74. The bottom wall of the emitter trench 74 may be formed parallel to the first principal surface 3. The bottom wall of the emitter trench 74 may be formed in a curved shape toward the second principal surface 4. The emitter trench 74 includes a bottom wall edge portion. The bottom wall edge portion connects the side walls and the bottom wall of the emitter trench 74. The bottom wall edge portion may be formed in a curved shape toward the second principal surface 4 of the semiconductor layer 2.

A depth D3 of the emitter trench 74 may be 2 μm or more and 10 μm or less. The depth D3 of the emitter trench 74 may be equal to the depth D1 of the first gate trench 39. A width of the emitter trench 74 may be 0.5 μm or more and 3 μm or less. The width of the emitter trench 74 is a width of the emitter trench 74 in the first direction X. The width of the emitter trench 74 may be equal to the width of the first gate trench 39.

The emitter insulating layer 75 is formed in a film shape along an inner wall of the emitter trench 74. The emitter insulating layer 75 defines a recessed space inside the emitter trench 74. In this preferred embodiment, the emitter insulating layer 75 includes a silicon oxide film. The emitter insulating layer 75 may include a silicon nitride film in place of, or in addition to the silicon oxide film.

The emitter potential electrode layer 76 is embedded in the emitter trench 74 across the emitter insulating layer 75. Specifically, the emitter potential electrode layer 76 is embedded in a recessed space that is defined by the emitter insulating layer 75 in the emitter trench 74. The emitter potential electrode layer 76 may contain a conductive polysilicon. The emitter potential electrode layer 76 is controlled by an emitter signal.

The emitter potential electrode layer 76 is formed in a wall shape extending along the normal direction Z in a cross-sectional view. The emitter potential electrode layer 76 has an upper end portion that is positioned at the opening side of the emitter trench 74. The upper end portion of the emitter potential electrode layer 76 is positioned at the bottom wall side of the emitter trench 74 with respect to the first principal surface 3.

A recess which is recessed toward the bottom wall of the emitter trench 74 is formed at the upper end portion of the emitter potential electrode layer 76. The recess at the upper end portion of the emitter potential electrode layer 76 is formed in a tapered shape toward the bottom wall of the emitter trench 74. The upper end portion of the emitter potential electrode layer 76 has a constricted portion constricted inside the emitter potential electrode layer 76.

Further, in this preferred embodiment, terminal trenches of the first trench gate structure 36 and the emitter trench structure 73 alternately arranged along the first direction X are the emitter trench structures 73. The terminal emitter trench structure 73 is referred to as a terminal emitter trench structure 73A. The terminal emitter trench structure 73A forms a boundary 72 between the IGBT region 8 and the diode region 9.

Referring to FIGS. 7A and 7B, as described above, each FET structure 35 includes the emitter region 46 and the contact region 50 at the first principal surface 3. On the first principal surface 3 of the IGBT region 8, the plurality of emitter regions 46 are arranged in a row along the first direction X. In other words, a plurality of emitter arrays 101 extending along the first direction X are arranged on the first principal surface 3 of the IGBT region 8. On the first principal surface 3, the contact region 50 is formed between a first emitter array L1 and a second emitter array L2.

Each emitter array 101 includes the plurality of emitter regions 46 arranged along the first direction X, and a part of the first trench gate structure 36 and a part of the emitter trench structure 73 sandwiched by the plurality of emitter regions 46 in the first direction X, respectively. Each emitter array 101 extends from one side to the other side in the first direction X of the IGBT region 8. Each emitter array 101 has an end portion on one side in the first direction X and an end portion on the other side (for example, the right side in FIGS. 7A and 7B) in the first direction X. Both end portions of each emitter array 101 are formed by the emitter regions 46. On the first principal surface 3 of the IGBT region 8, the plurality of emitter arrays 101 are arranged in the second direction Y. The plurality of emitter arrays 101 are formed in a stripe pattern as a whole.

The plurality of emitter arrays 101 have a constant width WA. The width WA of the emitter array 101 may be 0.5 μm or more and 2.0 μm or less. The width WA of the emitter array 101 is a width in the second direction Y. A distance (pitch PA) between the emitter arrays 101 adjacent to each other may be, for example, 0.5 μm or more and 10.0 μm or less.

The plurality of emitter arrays 101 include a plurality of first emitter arrays L1 and a plurality of second emitter arrays L2. The first emitter array L1 has an end portion on one side in the first direction X and an end portion on the other side (right side in FIG. 7A) in the first direction X. This end portion is referred to as a first end portion (an end portion on the diode region 9 side in the first emitter array L1) E1. The second emitter array L2 has an end portion on one side in the first direction X and an end portion on the other side (right side in FIG. 7A) in the first direction X. This end portion is referred to as a second end portion (an end portion on the diode region 9 side in the second emitter array L2) E2.

Referring to FIGS. 7A and 8, the first end portion E1 of the first emitter array L1 reaches the boundary 72 between the IGBT region 8 and the diode region 9. Specifically, the first end portion E1 of the first emitter array L1 is the emitter region 46 formed between the terminal emitter trench structure 73A and the first gate trench 39 closest to the diode region 9. The emitter region 46 is in contact with a side wall of the emitter trench 74 included in the terminal emitter trench structure 73A.

Referring to FIGS. 7A and 10, the second end portion E2 of the second emitter array L2 is separated from the boundary 72 between the IGBT region 8 and the diode region 9 on the side opposite to the diode region 9 side. In other words, the second end portion E2 of the second emitter array L2 is farther from the diode region 9 than the first end portion E1 of the first emitter array L1. In still other words, the second end portion E2 of the second emitter array L2 does not reach the boundary 72 between the IGBT region 8 and the diode region 9. Specifically, the second end portion E2 of the second emitter array L2 is the emitter region 46 formed between the first trench gate structure 36 third closest to the diode region 9 and the emitter trench structure 73 third closest to the terminal emitter trench structure 73A. The emitter region 46 is in contact with the side wall of the first gate trench 39 included in the first trench gate structure 36 third closest to the diode region 9.

On the first principal surface 3, a plurality of contact regions 50 are formed between the first emitter array L1 and the second emitter array L2 adjacent to each other. The plurality of contact regions 50 are arranged in a row along the first direction X between the first emitter array L1 and the second emitter array L2. A contact region 50 is formed in a region between the second emitter array L2 and the diode region 9 (specifically, a region between the first trench gate structure 36 third closest to the diode region 9 and the diode region 9) on the first principal surface 3. The contact region 50 is formed such as to be sandwiched between the second emitter array L2 and the diode region 9 on the first principal surface 3.

In the example of FIGS. 7A and 7B, the first emitter array L1 and the second emitter array L2 are alternately formed in the second direction Y. In FIGS. 7A and 7B, only two first emitter arrays L1 and three second emitter arrays L2 are shown. However, in the plurality of first emitter arrays L1 and the plurality of second emitter arrays L2, the first emitter array L1, the second emitter array L2, the first emitter array L1, and the second emitter array L2 . . . are repeated in the second direction Y from the end portion on the first outer trench gate structure 37 (see FIG. 3) side toward the end portion on the second outer trench gate structure 38 (see FIG. 3) side. In other words, the first emitter array L1 and the second emitter array L2 are arranged in the second direction Y in a constant repetitive pattern. In the example of FIG. 7A, in the plurality of second emitter arrays L2, a distance WE between the second end portion E2 of the second emitter array 2 and the diode region 9 is the same.

Attention is paid to the FET structure 35 included in the region 8A (hereinafter, referred to as a “near-boundary region 8A”) near the boundary 72 in the IGBT region 8. Of the plurality of FET structures (unit cells) 35, the FET structure closest to the diode region 9 will be referred to as a first FET structure (first unit cell) 35A, the FET structure second closest to the diode region 9 will be referred to as a second FET structure (first unit cell) 35B, the FET structure 35 third closest to the diode region 9 will be referred to as a third FET structure 35C, and the FET structure 35 fourth closest to the diode region 9 will be referred to as a fourth FET structure 35D in the following description. The FET structure farther from the diode region 9 than the fourth FET structure 35D is the same structure as the fourth FET structure 35D.

Referring to FIG. 7B, the FET structure formed in the central portion 8M of the IGBT region 8 is referred to as a central FET structure (second unit cell) 35M. The central FET structure 35M is the FET structure 35 far from the diode region 9. The central FET structure 35M has the same configuration as the fourth FET structure 35D.

Referring to FIGS. 7A and 7B, as described above, the second end portion E2 of the second emitter array L2 reaches only the first trench gate structure 36 that is third closest to the diode region 9. Therefore, among the plurality of FET structures 35 included in the IGBT region 8, the predetermined FET structures (the first FET structure 35A and the second FET structure 35B) included in the near-boundary region 8A have a smaller area (planar area) of the emitter region 46 and a larger area (planar area) of the contact region 50 than the central FET structure 35M at the central portion 8M of the IGBT region 8.

The area of the emitter region 46 formed in the first FET structure 35A is smaller than the area of the emitter region 46 formed in the central FET structure 35M. Specifically, the area of the emitter region 46 formed in the first FET structure 35A is 50% (½ times) of the area of the emitter region 46 formed in the central FET structure 35M.

In other words, the area of the contact region 50 formed in the first FET structure 35A is larger than the planar area of the contact region 50 formed in the central FET structure 35M. Specifically, the planar area of the contact region 50 formed in the first FET structure 35A is 150% of the planar area of the contact region 50 formed in the central FET structure 35M.

An interval WB (see FIG. 7A) between the emitter regions 46 adjacent in the second direction Y in the first FET structure 35A is larger than an interval WC (see FIG. 7B) between the emitter regions 46 adjacent in the second direction Y in the central FET structure 35M.

The area of the emitter region 46 formed in the second FET structure 35B is smaller than the area of the emitter region 46 formed in the central FET structure 35M. Specifically, the area of the emitter region 46 formed in the second FET structure 35B is 50% of the area of the emitter region 46 formed in the central FET structure 35M. In other words, the area of the contact region 50 formed in the second FET structure 35B is larger than the planar area of the contact region 50 formed in the central FET structure 35M. Specifically, the planar area of the contact region 50 formed in the second FET structure 35B is 150% of the planar area of the contact region 50 formed in the central FET structure 35M.

In the second FET structure 35B, an interval between the emitter regions 46 adjacent in the second direction Y is the same as the interval WB (see FIG. 7A).

As described above, the area of the emitter region 46 formed in the first and second FET structures 35A and 35B is smaller than the area of the emitter region 46 formed in the central FET structure 35M. Therefore, an area ratio of the emitter region 46 included in the first principal surface 3 of the near-boundary region 8A (the area of the emitter region 46/the entire area of the near-boundary region 8A) is smaller than an area ratio of the emitter region 46 included in the first principal surface 3 of the central portion 8M (the area of the emitter region 46/the entire area of the central portion 8M).

Referring to FIGS. 8 to 10, each diode region 9 includes an n⁺-type cathode region 61 formed in a surface layer portion of the second principal surface 4 of the semiconductor layer 2. An n-type impurity concentration of the cathode region 61 is higher than the n-type impurity concentration of the drift region 30. The n-type impurity concentration of the cathode region 61 may be 1.0×10¹⁹ cm⁻³ or more and 1.0×10²⁰ cm⁻³ or less.

The cathode region 61 is exposed from the second principal surface 4. The cathode region 61 forms an ohmic contact with the collector terminal electrode 32. The cathode region 61 is electrically connected to the collector region 34 at a side along the second direction Y. The cathode region 61 is surrounded by the collector region 34 of the IGBT region 8 in this preferred embodiment.

Referring to FIGS. 4 and 6, each diode region 9 includes a cell separating structure 63 that defines the diode cell region 69. In FIGS. 4 and 6, the cell separating structure 63 is indicated by hatching. Each diode region 9 specifically includes a plurality of cell separating structures 63 that each define a plurality of diode cell regions 69.

The plurality of cell separating structures 63 are formed in regions between the plurality of diode cell regions 69 adjacent to each other, respectively. Specifically, each of the plurality of cell separating structures 63 is formed in an annular shape (quadrangular annular shape in this preferred embodiment) surrounding the diode cell region 69 in a plan view. The cell separating structure 63 that defines one diode cell region 69 and the cell separating structure 63 that defines the other diode cell region 69 are integrally formed in a region between the plurality of diode cell regions 69 adjacent to each other.

The plurality of cell separating structures 63 may be arranged at equal intervals in the first direction X. The plurality of cell separating structures 63 are formed in a stripe pattern. A distance (second pitch P2 (see FIG. 6)) between two cell separating structures 63 adjacent to each other in the first direction X may be, for example, 1.0 μm or more and 10.0 μm or less. The second pitch P2 may be the same as the first pitch P1 (see FIG. 5).

In this preferred embodiment, a plurality of diode cell regions 69 defined by the plurality of cell separating structures 63 are formed at intervals along the first direction X in a plan view. The plurality of diode cell regions 69 are each formed in a band shape extending along the second direction Y in a plan view. The plurality of diode cell regions 69 are formed in a stripe pattern as a whole. With respect to the second direction Y, a length of the diode cell region 69 may be equal to or less than a length of the first trench gate structure 36. The length of the diode cell region 69 may be less than the length of the first trench gate structure 36.

Referring to FIGS. 8 to 10, the cell separating structure 63 includes a cell separation trench 64, a cell separation insulating layer 65, and a cell separation electrode layer 66. The cell separation trench 64 is formed on the first principal surface 3. The cell separation trench 64 includes a side wall and a bottom wall. The side wall of the cell separation trench 64 may be formed perpendicular to the first principal surface 3.

The side wall of the cell separation trench 64 may be inclined downward from the first principal surface 3 toward the bottom wall. The cell separation trench 64 may be formed in a tapered shape in which the opening area on the opening side is larger than the bottom area. The bottom wall of the cell separation trench 64 may be formed in parallel with the first principal surface 3. The bottom wall of the cell separation trench 64 may be formed in a curved shape toward the second principal surface 4. The cell separation trench 64 includes a bottom wall edge portion. The bottom wall edge portion connects the side wall and the bottom wall of the cell separation trench 64. The bottom wall edge portion may be formed in a curved shape toward the second principal surface 4.

A depth D2 of the cell separation trench 64 may be 2 μm or more and 10 μm or less. The depth D2 of the cell separation trench 64 may be defined as a distance between a depth position of the deepest portion of the bottom wall of the cell separation trench 64 and the first principal surface 3. The depth D2 of the cell separation trench 64 may be equal to the depth D1 (see FIG. 8) of the first gate trench 39. A width of the cell separation trench 64 may be 0.5 μm or more and 3 μm or less. The width of the cell separation trench 64 is the width of the cell separation trench 64 in the first direction X. The width of the cell separation trench 64 may be equal to the width of the first gate trench 39.

The cell separation insulating layer 65 is formed in a film shape along the inner wall of the cell separation trench 64. The cell separation insulating layer 65 defines a recessed space in the cell separation trench 64. The cell separation insulating layer 65 includes a silicon oxide film in this preferred embodiment. The cell separation insulating layer 65 may include a silicon nitride film instead of or in addition to the silicon oxide film.

The cell separation electrode layer 66 is embedded in the cell separation trench 64 with the cell separation insulating layer 65 interposed therebetween. Specifically, the cell separation electrode layer 66 is embedded in a recessed space defined by the cell separation insulating layer 65 in the cell separation trench 64. The cell separation electrode layer 66 is controlled by an emitter signal. The cell separation electrode layer 66 may contain conductive polysilicon.

The cell separation electrode layer 66 is formed in a wall shape extending along the normal direction Z in a cross-sectional view. The cell separation electrode layer 66 has an upper end portion located on the opening side of the cell separation trench 64. The upper end portion of the cell separation electrode layer 66 is located on the bottom wall side of the cell separation trench 64 with respect to the first principal surface 3.

The upper end portion of the cell separation electrode layer 66 is formed in a tapered shape toward the first principal surface 3 side. A recess recessed toward the bottom wall of the cell separation trench 64 is formed at the upper end portion of the cell separation electrode layer 66. The recess of the cell separation electrode layer 66 is formed in a tapered shape toward the bottom wall of the cell separation trench 64.

Each diode region 9 includes a p⁻-type anode region 62 formed on the surface layer portion of the first principal surface 3 of the semiconductor layer 2. A p-type impurity concentration of the anode region 62 may be equal to or lower than the p-type impurity concentration of the body region 45. The p-type impurity concentration of the anode region 62 is preferably less than the p-type impurity concentration of the body region 45. The p-type impurity concentration of the anode region 62 may be 1.0×10¹⁵ cm⁻³ or more and less than 1.0×10¹⁸ cm⁻³.

The anode region 62 is formed in each diode cell region 69. Therefore, the plurality of anode regions 62 are arranged at equal intervals in the first direction X, and is formed in a stripe pattern as a whole. The anode region 62 forms a pn joint portion 68 with the semiconductor layer 2. A pn joint diode D, having the anode region 62 as an anode and the semiconductor layer 2 (cathode region 61) as a cathode, is thereby formed.

In this preferred embodiment, a boundary between the collector region 34 and the cathode region 61 is aligned with the boundary 72 between the IGBT region 8 and the diode region 9 in a plan view.

In the cell separation trench 64, a recess 67 is defined by a side wall of the cell separation trench 64, an upper end portion of the cell separation electrode layer 66, and an upper end portion of the cell separation insulating layer 65. A wide-width portion of the cell separation trench 64 is formed by the recess 67. A side wall of the recess 67 (a side wall of the cell separation trench 64) exposes the anode region 62.

As described above, the side wall of the terminal emitter trench structure 73A closer to the diode region 9 forms the boundary 72 between the IGBT region 8 and the diode region 9. In a region between the terminal emitter trench structure 73A and the cell separating structure 63 closest to the IGBT region 8, similarly to the FET structure 35, the body region 45 and the carrier storage region 47 are formed in order from the first principal surface 3 side. On the other hand, this region may be referred to as a dummy FET structure 42 because the emitter region 46 is not formed and this region does not form a channel. The dummy FET structure 42 is formed in the diode region 9.

Referring to FIGS. 8 to 11, the semiconductor device 1 includes an interlayer insulating layer 79 formed on the first principal surface 3 of the semiconductor layer 2. The interlayer insulating layer 79 is formed in a film shape along the first principal surface 3 and selectively covers the first principal surface 3. Specifically, the interlayer insulating layer 79 selectively covers the IGBT region 8 and the diode region 9.

The interlayer insulating layer 79 may contain silicon oxide or silicon nitride. The interlayer insulating layer 79 may contain at least one of non-doped silicate glass (NSG), phosphor silicate glass (PSG), and boron phosphor silicate glass (BPSG). A thickness of the interlayer insulating layer 79 may be 0.1 μm or more and 1 μm or less.

In this preferred embodiment, the interlayer insulating layer 79 has a laminated structure including a first insulating layer 80, a second insulating layer 81, and a third insulating layer 82 laminated in this order from the first principal surface 3 side. The first insulating layer 80 may contain silicon oxide (for example, a thermal oxide film). The second insulating layer 81 may include an NGS layer, a PSG layer, or a BPSG layer. The third insulating layer 82 may include a BPSG layer, an NGS layer, or a PSG layer. The third insulating layer 82 may contain an insulating material having a property different from that of the second insulating layer 81.

The first insulating layer 80 is formed in a film shape on the first principal surface 3. The first insulating layer 80 is continuous with the first gate insulating layer 40, the region separating insulating layer 55, and the cell separation insulating layer 65. A thickness of the first insulating layer 80 may be 500 Å or more and 2000 Å or less. The second insulating layer 81 is formed in a film shape on the first insulating layer 80. A thickness of the second insulating layer 81 may be 500 Å or more and 4000 Å or less. The third insulating layer 82 is formed in a film shape on the second insulating layer 81. A thickness of the third insulating layer 82 may be 1000 Å or more and 8000 Å or less.

Referring to FIG. 11, the first gate conductive layer 41 of the FET structure 35 includes a gate lead-out electrode layer 41a extended from the first gate trench 39 onto the first principal surface 3. The gate lead-out electrode layer 41a is extended from the first gate trench 39 of the first outer trench gate structure 37 onto the first principal surface 3. The gate lead-out electrode layer 41a is extended along the second direction Y.

Specifically, the gate lead-out electrode layer 41a is formed inside the interlayer insulating layer 79. The gate lead-out electrode layer 41a is extended onto the first insulating layer 80 and is interposed in a region between the first insulating layer 80 and the second insulating layer 81. The gate lead-out electrode layer 41a is electrically connected to the gate wiring 19 (see FIG. 1) in a region (not illustrated). The gate signal applied to the gate terminal electrode 14 is transmitted to the first gate conductive layer 41 through the gate wiring 19 and the gate lead-out electrode layer 41a.

The emitter potential electrode layer 76 of the emitter trench structure 73 has a lead-out electrode layer 76a extended from the emitter trench 74 onto the first principal surface 3. The emitter potential electrode layer 76 is extended along the second direction Y.

The lead-out electrode layer 76a is specifically formed inside the interlayer insulating layer 79. The lead-out electrode layer 76a is extended onto the first insulating layer 80 and is interposed in a region between the first insulating layer 80 and the second insulating layer 81. The lead-out electrode layer 76a is electrically connected to the emitter terminal electrode 13. The emitter signal applied to the lead-out electrode layer 76a is transmitted to the emitter potential electrode layer 76 through the lead-out electrode layer 76a.

Referring to FIGS. 8 to 10, the interlayer insulating layer 79 includes an emitter opening 83. The emitter opening 83 exposes the contact trench 48. The emitter opening 83 communicates with the contact trench 48. In this preferred embodiment, the contact trench 48 is formed on the first principal surface 3 through the first insulating layer 80 and the second insulating layer 81.

The emitter opening 83 penetrates through the third insulating layer 82 and exposes the contact trench 48. The emitter opening 83 forms one opening with the contact trench 48. An opening edge portion of the emitter opening 83 is formed in a curved shape toward the inside of the interlayer insulating layer 79. Accordingly, the emitter opening 83 has an opening width larger than the opening width of the contact trench 48.

The interlayer insulating layer 79 includes a diode opening 84. The diode opening 84 exposes the diode region 9. Specifically, the diode opening 84 penetrates through the interlayer insulating layer 79 and exposes the plurality of anode regions 62 (diode cell regions 69) and the plurality of cell separating structures 63.

A portion of the inner wall of the diode opening 84 along the second direction Y may be located on the anode region 62. A portion of the inner wall of the diode opening 84 along the second direction Y may be located on the cell separating structure 63. In the examples of FIGS. 8 to 10, a portion of the inner wall of the diode opening 84 along the second direction Y is located on the body region 45 of the dummy FET structure 42.

Referring to FIG. 11, the interlayer insulating layer 79 includes a first opening 86. The first opening 86 exposes the lead-out electrode layer 76a in the IGBT region 8. The first opening 86 is formed such that an opening width decreases from the opening side toward the bottom wall side.

Referring to FIGS. 8 to 10, the semiconductor device 1 includes an emitter plug electrode 91 embedded in a portion covering the IGBT region 8 in the interlayer insulating layer 79. The emitter plug electrode 91 penetrates through the interlayer insulating layer 79 and is electrically connected to the emitter region 46 and the contact region 50. Specifically, the emitter plug electrode 91 is embedded in the contact trench 48. The emitter plug electrode 91 is electrically connected to the emitter region 46 and the contact region 50 in the contact trench 48. The emitter plug electrode 91 is indicated by a broken line in FIGS. 7A and 7B.

In this preferred embodiment, the emitter plug electrode 91 has a laminated structure including a barrier electrode layer 92 and a principal electrode layer 93. The barrier electrode layer 92 is formed in a film shape along the inner wall of the contact trench 48 such as to be in contact with the interlayer insulating layer 79. The barrier electrode layer 92 defines a recessed space in the contact trench 48.

The barrier electrode layer 92 may have a single-layered structure including a titanium layer or a titanium nitride layer. The barrier electrode layer 92 may have a laminated structure including a titanium layer and a titanium nitride layer. In this case, the titanium nitride layer may be laminated on the titanium layer.

The principal electrode layer 93 is embedded in the contact trench 48 with the barrier electrode layer 92 interposed therebetween. Specifically, the principal electrode layer 93 is embedded in a recessed space defined by the barrier electrode layer 92 in the contact trench 48. The principal electrode layer 93 may contain tungsten.

Referring to FIG. 11, the semiconductor device 1 includes a first plug electrode 94 embedded in the first opening 86. The first plug electrode 94 is electrically connected to the lead-out electrode layer 76a in the first opening 86. The first plug electrode 94 has a structure corresponding to the emitter plug electrode 91. The description of the emitter plug electrode 91 applies mutatis mutandis to the description of the first plug electrode 94. Structures of the first plug electrode 94 corresponding to the structures described for the emitter plug electrode 91 are denoted by the same reference numerals, and description thereof is omitted.

Referring to FIGS. 8 to 11, the above-described emitter terminal electrode 13 is formed on the interlayer insulating layer 79. The emitter terminal electrode 13 may contain at least one among aluminum, copper, an aluminum-silicon-copper alloy, an aluminum-silicon alloy, and an aluminum-copper alloy. The emitter terminal electrode 13 may have a single-layered structure containing any one of these conductive materials. The emitter terminal electrode 13 may have a laminated structure in which at least two of these conductive materials are laminated in a random order. A thickness of the emitter terminal electrode 13 may be 1.0 μm or more and 6.0 μm or less.

In this preferred embodiment, the emitter terminal electrode 13 has a laminated structure including a first electrode layer 22, a second electrode layer 23, and a third electrode layer 24 laminated in this order from the first principal surface 3 side. The first electrode layer 22 may contain an aluminum-silicon-copper alloy (Al—Si—Cu). The second electrode layer 23 may contain titanium nitride (TiN). The second electrode layer 23 may be referred to as a barrier layer. The third electrode layer 24 may contain an aluminum-copper alloy (Al—Cu).

The emitter terminal electrode 13 is electrically connected to the emitter region 46 and the contact region 50 through the emitter plug electrode 91 on the interlayer insulating layer 79. Specifically, the emitter terminal electrode 13 enters the emitter opening 83 from above the interlayer insulating layer 79. The emitter terminal electrode 13 is electrically connected to the emitter plug electrode 91 at the emitter opening 83. The emitter terminal electrode 13 is electrically connected to the emitter region 46 and the contact region 50 through the emitter plug electrode 91.

Referring to FIGS. 8 to 10, the emitter terminal electrode 13 further enters the diode opening 84 from above the interlayer insulating layer 79 through the inner wall of the diode opening 84. The emitter terminal electrode 13 functions as an anode terminal electrode in the diode region 9.

The emitter terminal electrode 13 is in contact with the inner wall of the diode opening 84. The emitter terminal electrode 13 is electrically connected to the anode region 62 in the diode opening 84. The emitter terminal electrode 13 is electrically connected to the cell separation electrode layer 66 in the diode opening 84. The emitter terminal electrode 13 is directly connected to the anode region 62 and the cell separation electrode layer 66 in this preferred embodiment.

Specifically, the emitter terminal electrode 13 enters the recess 67 (cell separation trench 64) from above the first principal surface 3 in the diode opening 84. The emitter terminal electrode 13 is connected to the cell separation electrode layer 66 in the recess 67. The emitter terminal electrode 13 is connected to the anode region 62 on the first principal surface 3 and in the recess 67. The emitter terminal electrode 13 forms an ohmic contact with the anode region 62.

Referring to FIG. 11, the emitter terminal electrode 13 is electrically connected to the first plug electrode 94 on the interlayer insulating layer 79. The emitter signal is transmitted to the emitter potential electrode layer 76 through the first plug electrode 94.

Although not specifically illustrated, when a conducting wire (for example, a bonding wire) is connected to the emitter terminal electrode 13, a single-layered electrode composed of a nickel layer or a gold layer, or a laminated electrode including a nickel layer and a gold layer may be formed on the emitter terminal electrode 13. In the laminated electrode, the gold layer may be formed on the nickel layer.

Although not specifically illustrated, the gate terminal electrode 14, the first sense terminal electrode 15, the second sense terminal electrode 16, the current detection terminal electrode 17, and the open terminal electrode 18 are formed on the interlayer insulating layer 79 similarly to the emitter terminal electrode 13.

The plurality of terminal electrodes 14 to 18 may each contain at least one among aluminum, copper, an aluminum-silicon-copper alloy, an aluminum-silicon alloy, and an aluminum-copper alloy. Each of the plurality of terminal electrodes 14 to 18 may have a single-layered structure containing any one of these conductive materials. The plurality of terminal electrodes 14 to 18 may each have a laminated structure in which at least two of these conductive materials are laminated in a random order. In this preferred embodiment, the plurality of terminal electrodes 14 to 18 include the same conductive material as the emitter terminal electrode 13.

When a conducting wire (for example, a bonding wire) is connected to each of the plurality of terminal electrodes 14 to 18, a single-layered electrode formed of a nickel layer or a gold layer, or a laminated electrode including a nickel layer and a gold layer may be formed on each of the plurality of terminal electrodes 14 to 18. In the laminated electrode, the gold layer may be formed on the nickel layer.

As described above, according to this preferred embodiment, the area of the emitter region 46 formed in the predetermined FET structure 35 (first and second FET structures 35A and 35B) included in the near-boundary region 8A is smaller than the area of the emitter region 46 formed in the central FET structure 35M. Therefore, the area ratio of the emitter region 46 included in the first principal surface 3 of the near-boundary region 8A is smaller than the area ratio of the emitter region 46 included in the first principal surface 3 of the central portion 8M. Therefore, the number of parasitic transistors (the number of npn transistors) in the near-boundary region 8A can be reduced. By reducing an area ratio of the emitter region 46 in the near-boundary region 8A, it is possible to suppress the snapback phenomenon in the semiconductor device 1 while suppressing the deterioration of the forward voltage.

The repetitive pattern of the first emitter array L1 and the second emitter array L2 is not limited to the alternately repetitive pattern illustrated in FIG. 7A.

For example, in the second direction Y, one second emitter array L2 may be formed every other of the plurality of first emitter arrays L1. In the second direction Y, one first emitter array L1 may be formed every other of the plurality of second emitter arrays L2. In the second direction Y, the second number of second emitter arrays L2 may be formed every other first number of first emitter arrays L1. The second number may be larger than the first number. The second number may be smaller than the first number. The second number may be the same as the first number.

By changing a ratio between the first emitter array L1 and the second emitter array L2 included in one repetitive pattern, an area ratio of the emitter region 46 included in the first principal surface 3 of the near-boundary region 8A (the area of the emitter region 46/the entire area of the near-boundary region 8A) can be adjusted. A ratio of the second emitter array L2 included in one repetitive pattern may be made larger than a ratio of the first emitter array L1 included in the repetitive pattern. In this case, the area of the emitter region 46 formed in the first or second FET structures 35A and 35B is less than 50% (less than ½ times) of the area of the emitter region 46 formed in the central FET structure 35M. On the other hand, the ratio of the second emitter array L2 included in one repetitive pattern may be made smaller than the ratio of the first emitter array L1 included in the repetitive pattern. In this case, the area of the emitter region 46 formed in the first or second FET structures 35A and 35B is more than 50% and less than 100% (more than ½ times) of the area of the emitter region 46 formed in the central FET structure 35M.

The distance WE between the second end portion E2 of the second emitter array L2 and the diode region 9 is not limited to the distance illustrated in FIG. 7A. For example, the second end portion E2 of each second emitter array L2 may reach the first trench gate structure 36 second closest to the diode region 9. The second end portion E2 of the second emitter array L2 may reach only the first trench gate structure 36 n-th (n>4) closest to the diode region 9. By changing the distance WE, the area ratio of the emitter region 46 included in the first principal surface 3 of the near-boundary region 8A can be adjusted.

That is, by changing at least one of the ratio of the first emitter array L1 and the second emitter array L2 included in one repetitive pattern and the distance WE, the area ratio of the emitter region 46 included in the first principal surface 3 of the near-boundary region 8A can be adjusted.

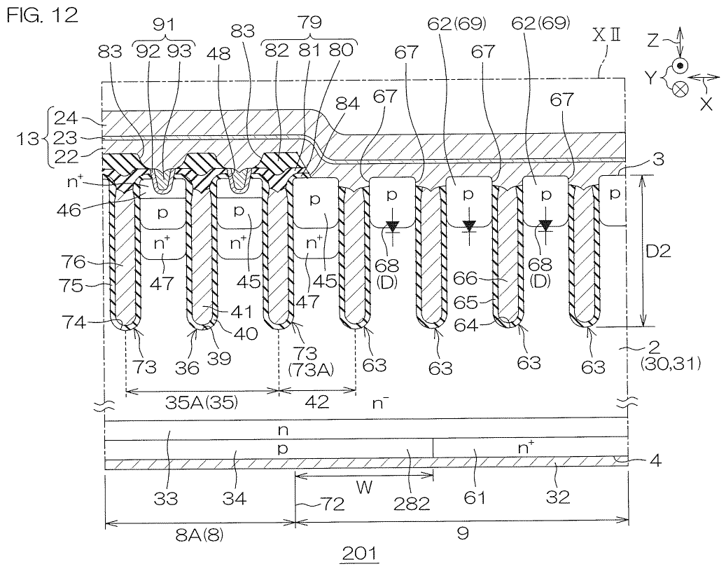

FIG. 12 is a cross-sectional view of a semiconductor device 201 according to a second preferred embodiment of the present disclosure. FIG. 12 is a cross-sectional view corresponding to a cross-section taken along line XII-XII in FIG. 6. In the second preferred embodiment, only portions different from those of the first preferred embodiment will be mainly described, and the same components as those described so far are denoted by the same reference numerals, and description thereof will be omitted.

The semiconductor device 201 according to the second preferred embodiment is different from the semiconductor device 1 according to the first preferred embodiment in that the collector region 34 includes a lead-out region 282. The lead-out region 282 is a region led out toward the diode region 9 across the boundary 72 between the IGBT region 8 and the diode region 9. The lead-out region 282 is led out from the IGBT region 8 to the diode region 9 along the first direction X.

The lead-out region 282 overlaps the diode region 9 with a predetermined overlap width W. A start point of the overlap width W is set at the boundary 72 between the IGBT region 8 and the diode region 9. An end point of the overlap width W is set at the boundary between the lead-out region 282 and the cathode region 61. A threshold value (Vth) in the IGBT region 8 is lowered by the collector region 34. Therefore, since the collector region 34 includes the lead-out region 282, a snapback phenomenon can be suppressed in the semiconductor device 201.

A ratio W/WD of the overlap width W to the width WD (see FIG. 3) of the diode region 9 may be 0.001 or more and 0.5 or less. The ratio W/WD may be 0.001 or more and 0.01 or less, 0.01 or more and 0.05 or less, 0.05 or more and 0.1 or less, 0.1 or more and 0.15 or less, 0.15 or more and 0.2 or less, 0.2 or more and 0.25 or less, 0.25 or more and 0.3 or less, 0.3 or more and 0.35 or less, 0.35 or more and 0.4 or less, 0.4 or more and 0.45 or less, or 0.45 or more and 0.5 or less.

The overlap width W may be 1 μm or more and 200 μm or less. The overlap width W may be 1 μm or more and 50 μm or less, 50 μm or more and 100 μm or less, 100 μm or more and 150 μm or less, or 150 μm or more and 200 μm or less.

The overlap width W may be 1 μm or more and 20 μm or less, 20 μm or more and 40 μm or less, 40 μm or more and 60 μm or less, 60 μm or more and 80 μm or less, 80 μm or more and 100 μm or less, 100 μm or more and 120 μm or less, 120 μm or more and 140 μm or less, 140 μm or more and 160 μm or less, 160 μm or more and 180 μm or less, or 180 μm or more and 200 μm or less. The overlap width W is preferably 10 μm or more and 150 μm or less.

The lead-out region 282 may oppose one or more anode regions 62 (diode cell regions 69) in the normal direction Z. The lead-out region 282 may oppose 1, 2, 3, 4, 5, 6, 7, 8, 9, 10, 11, 12, 13, 14, 15, 16, 17, 18, 19, or 20 anode regions 62. The lead-out region 282 preferably opposes 1 or more and 10 or less anode regions 62.

In the semiconductor device 201, both a configuration in which the area ratio of the emitter region 46 included in the first principal surface 3 of the near-boundary region 8A is smaller than the area ratio of the emitter region 46 included in the first principal surface 3 of the central portion 8M and a configuration in which the collector region 34 includes the lead-out region 282 are adopted. Therefore, even if the area ratio of the emitter region 46 included in the first principal surface 3 of the near-boundary region 8A is increased as compared with the case of the semiconductor device 1 according to the first preferred embodiment, the snapback phenomenon can be suppressed.

In the semiconductor device 201, the area ratio of the emitter region 46 included in the first principal surface 3 of the near-boundary region 8A (the area of the emitter region 46/the entire area of the near-boundary region 8A) may be made larger than the area ratio of the emitter region 46 included in the first principal surface 3 of the near-boundary region 8A in the semiconductor device 1 according to the first preferred embodiment.

In this case, in the semiconductor device 201, the region that effectively functions as the IGBT in the IGBT region 8 can be increased as compared with the semiconductor device 1. Accordingly, in the semiconductor device 201, the snapback phenomenon can be suppressed while sufficiently securing the amount of current flowing through the IGBT region 8.

As described above, the adjustment of the area ratio of the emitter region 46 included in the first principal surface 3 of the near-boundary region 8A is performed by changing at least one of the number ratio of the first emitter array L1 and the second emitter array L2 included in one repetitive pattern and the distance WE.

On the other hand, a case where the snapback phenomenon is suppressed only by the lead-out region 282 of the collector region 34, that is, a case where the area ratio of the emitter region 46 included in the first principal surface 3 of the near-boundary region 8A is equal to the area ratio of the emitter region 46 included in the first principal surface 3 of the central portion 8M will be considered. In this case, it is necessary to sufficiently widen the overlap width W.

On the other hand, in the semiconductor device 201, the area ratio of the emitter region 46 included in the first principal surface 3 of the near-boundary region 8A is smaller than the area ratio of the emitter region 46 included in the first principal surface 3 of the central portion 8M. Therefore, even if the overlap width W is made relatively narrow, the snapback phenomenon in the semiconductor device 201 can be suppressed.

By narrowing the overlap width W, it is possible to increase a region that effectively functions as a diode in the diode region 9. Therefore, the amount of current flowing through the diode region 9 can be increased as compared with the case where the snapback phenomenon is suppressed only by the lead-out region 282 of the collector region 34. Accordingly, in the semiconductor device 201, the snapback phenomenon can be suppressed while sufficiently securing the amount of current flowing through the diode region 9.

The optimum overlap width W and the optimum area ratio of the emitter region 46 included in the first principal surface 3 of the near-boundary region 8A are determined based on the balance between the amount of current flowing through the IGBT region 8 and the amount of current flowing through the diode region 9.

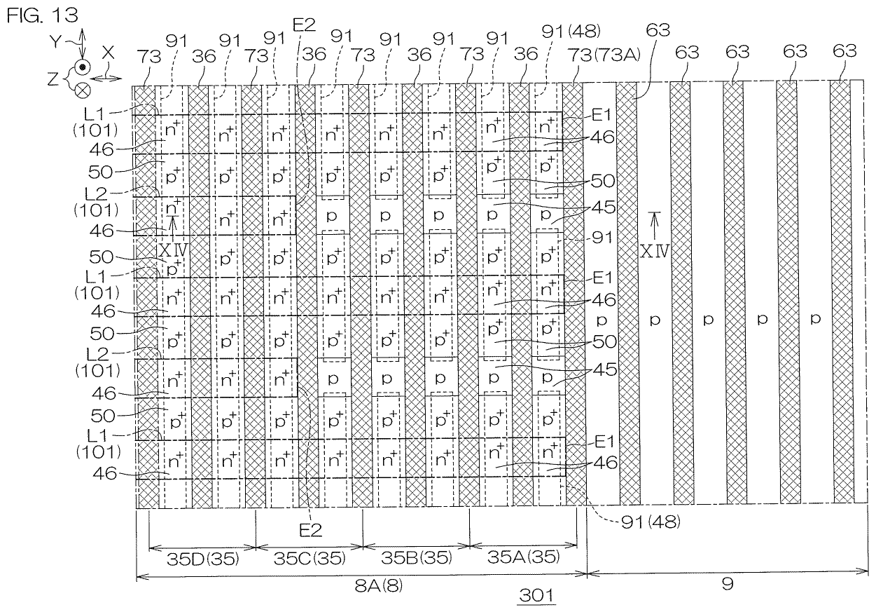

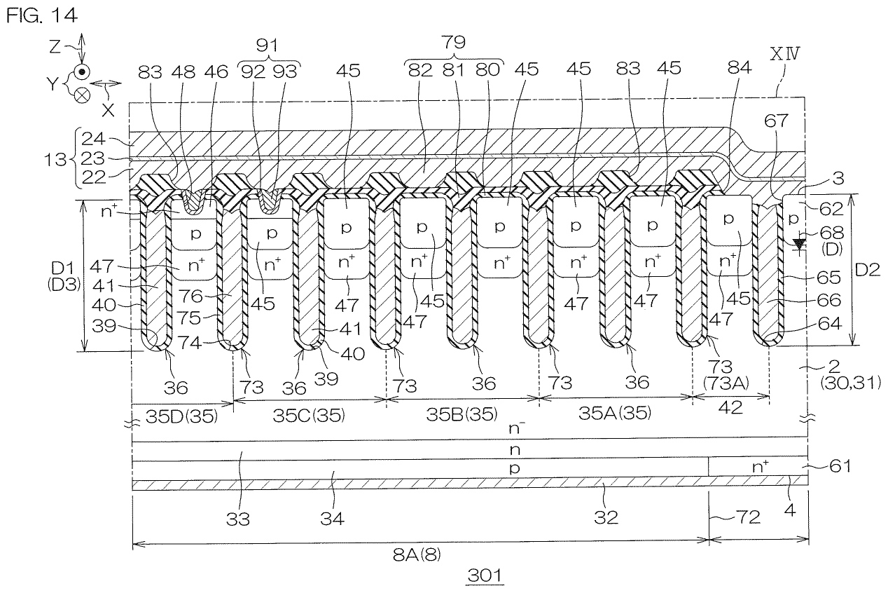

FIG. 13 is an enlarged view of a semiconductor device 301 according to a third preferred embodiment of the present disclosure, and is a view corresponding to FIG. 7A. FIG. 14 is a cross-sectional view taken along line XIV-XIV shown in FIG. 13. In the third preferred embodiment, only portions different from those of the first preferred embodiment will be mainly described, and the same components as those described so far are denoted by the same reference numerals, and description thereof will be omitted.

Referring to FIG. 13, the semiconductor device 301 according to the second preferred embodiment is different from the semiconductor device 1 according to the first preferred embodiment in that the contact region 50 is not formed between the second emitter array L2 and the diode region 9 on the first principal surface 3.

Referring to FIGS. 13 and 14, on the first principal surface 3 of the semiconductor device 301, the emitter region 46 and the contact region 50 are not formed in the region between the second emitter array L2 and the diode region 9. In this region, the body region 45 is exposed to the first principal surface 3. In other words, on the first principal surface 3, the body region 45 is sandwiched between the second emitter array L2 and the diode region 9.

On the first principal surface 3, the contact trench 48 is not formed in the region between the second emitter array L2 and the diode region 9. That is, the contact trench 48 is divided in the region between the second emitter array L2 and the diode region 9 on the first principal surface 3. Therefore, the emitter plug electrode 91 is not formed in this region.

According to this preferred embodiment, hole injection into the diode can be suppressed by reducing the area of the contact region 50, and thus, the switching loss of the diode can be reduced.

In addition, the third preferred embodiment illustrated in FIGS. 13 and 14 may be combined with the semiconductor device 201 according to the second preferred embodiment.

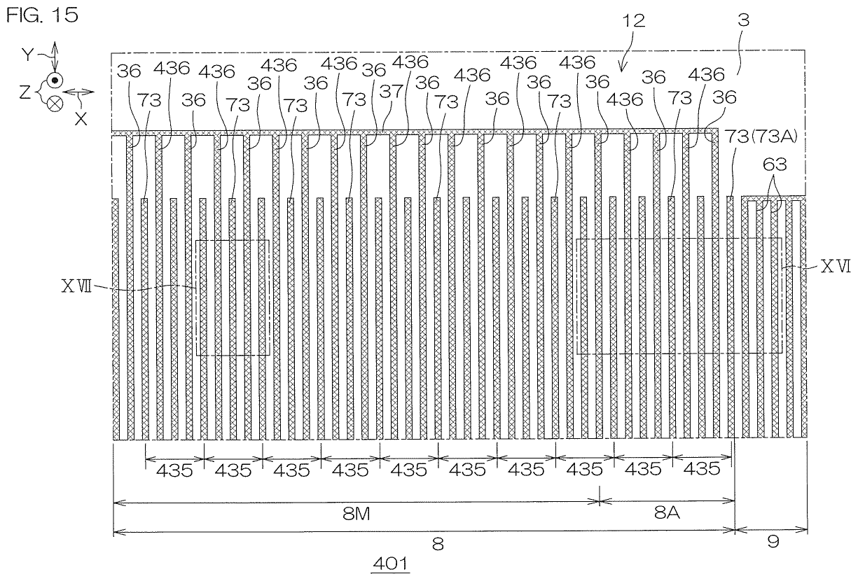

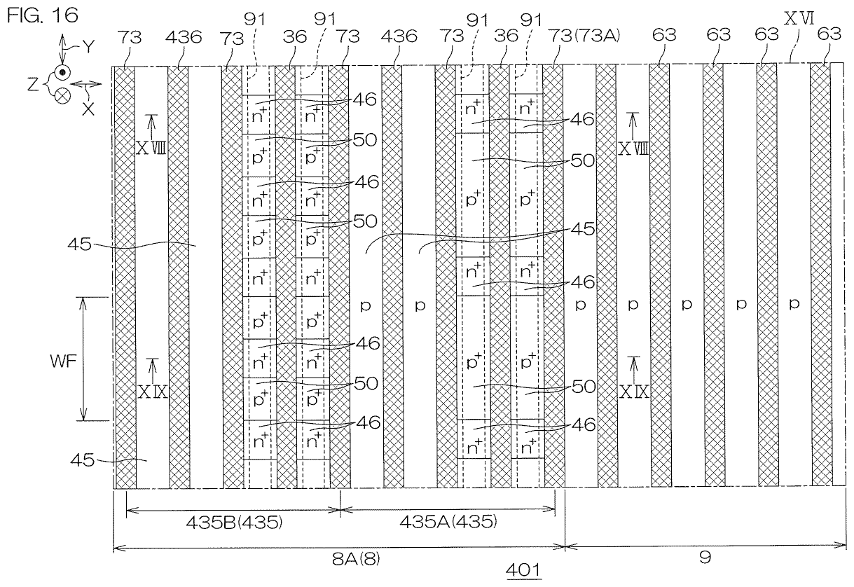

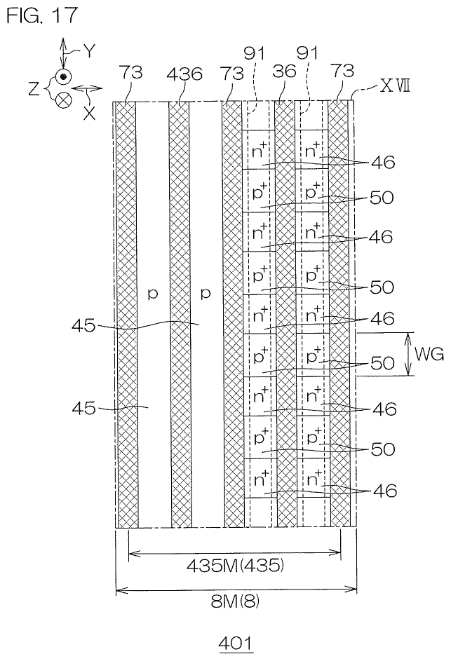

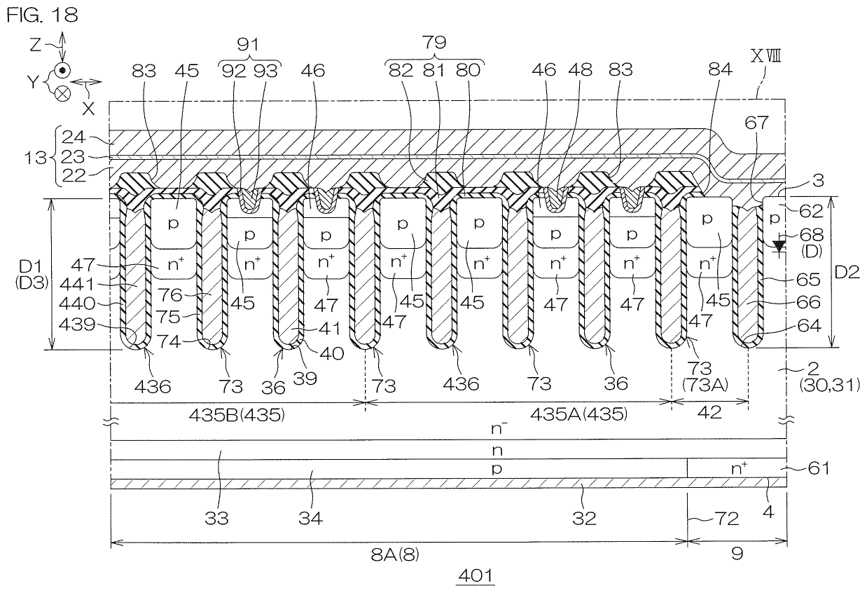

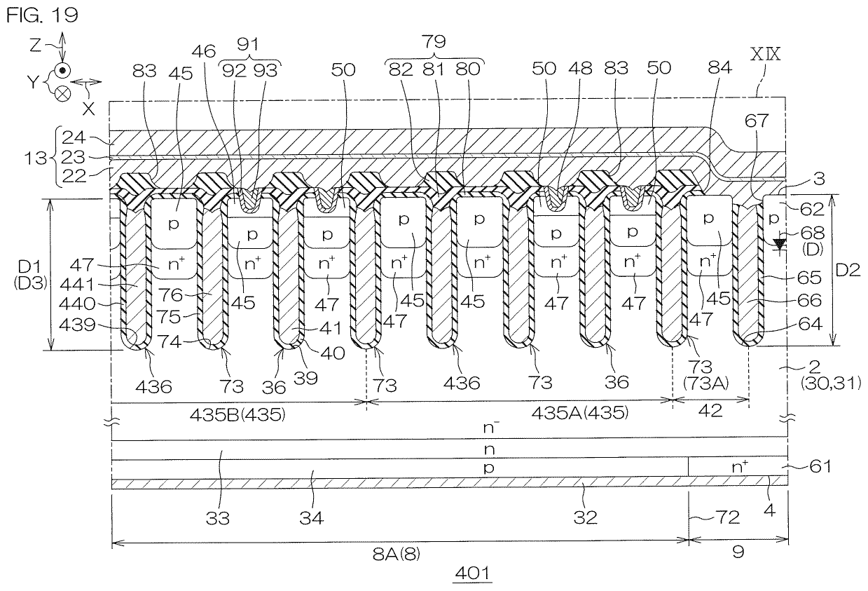

FIG. 15 is an enlarged view of a semiconductor device 401 according to a fourth preferred embodiment of the present disclosure, and is a view corresponding to FIG. 4. FIG. 16 is an enlarged view of a portion surrounded by an alternate long and short dashed line XVI in FIG. 15. FIG. 17 is an enlarged view of a portion surrounded by an alternate long and short dashed line XVII in FIG. 15. FIG. 18 is a cross-sectional view taken along line XVIII-XVIII in FIG. 16. FIG. 19 is a cross-sectional view taken along line XIX-XIX in FIG. 16. In FIGS. 15 to 19, the same reference numerals as those in FIGS. 1 to 11 are given to structures common to those in the first preferred embodiment, and description thereof is omitted.

Referring to FIGS. 15 to 19, the semiconductor device 401 according to the fourth preferred embodiment is different from the semiconductor device 1 according to the first preferred embodiment in that the IGBT region 8 includes a second trench gate structure 436 as a trench gate structure in addition to the first trench gate structure 36, and the IGBT region 8 includes an FET structure 435 as a unit cell instead of the FET structure 35.

Referring to FIG. 15, a plurality of second trench gate structures 436 is formed at intervals along the first direction X in the IGBT region 8. The plurality of second trench gate structures 436 are formed adjacent to the plurality of first trench gate structures 36. The plurality of first trench gate structures 36 and the plurality of second trench gate structures 436 are formed in a stripe pattern as a whole. In other words, the plurality of second trench gate structures 436 form a ladder type trench structure with the plurality of first trench gate structures 36.

In the example of FIG. 15, the first trench gate structures 36 and the second trench gate structures 436 are alternately arranged one by one in the first direction X. In other words, one second trench gate structure 436 is formed between adjacent first trench gate structures 36. The second trench gate structure 436 is formed in a band shape along the second direction Y in which the first trench gate structure 36 extends. The second trench gate structure 436 is formed spaced apart from the first trench gate structure 36 in the first direction X. A distance between the first trench gate structure 36 and the second trench gate structure 436 adjacent to each other may be 1 μm or more and 8 μm or less. In the examples of FIGS. 15 to 17, the first trench gate structure 36 and the second trench gate structure 436 are indicated by hatching.

Referring to FIG. 15, each of the plurality of second trench gate structures 436 has one end portion on one side in the second direction Y and the other end portion on the other side in the second direction Y. One end portions of the plurality of second trench gate structures 436 are electrically and mechanically connected to the first outer trench gate structure 37. The first outer trench gate structure 37 connects one end portions of the plurality of first trench gate structures 36 and one end portions of the plurality of second trench gate structures 436. The other end portions of the plurality of second trench gate structures 436 are electrically and mechanically connected to the second outer trench gate structure 38 (see FIG. 3). The second outer trench gate structure 38 connects the other end portions of the plurality of first trench gate structures 36 and the other end portions of the plurality of second trench gate structures 436.

Referring to FIGS. 18 and 19, each second trench gate structure 436 includes a second gate trench (gate trench) 439, a second gate insulating layer (gate insulating layer) 440, and a second gate conductive layer (gate conductive layer) 441. The second gate trench 439 includes a side wall and a bottom wall. The side wall of the second gate trench 439 may be formed perpendicular with respect to the first principal surface 3. The side wall of the second gate trench 439 may be inclined downwardly from the first principal surface 3 to the bottom wall. The bottom wall of the second gate trench 439 may be formed parallel to the first principal surface 3. The bottom wall of the second gate trench 439 may be formed in a curved shape toward the second principal surface 4. The second gate trench 439 includes a bottom wall edge portion connecting the side wall and the bottom wall of the second gate trench 439. The bottom wall edge portion may be formed in a curved shape toward the second principal surface 4.

The second gate insulating layer 440 is formed in a film shape along an inner wall of the second gate trench 439. The second gate insulating layer 440 defines a recessed space inside the second gate trench 439. In this preferred embodiment, the second gate insulating layer 440 includes a silicon oxide film. The second gate insulating layer 440 may include a silicon nitride film in place of, or in addition to the silicon oxide film.

The second gate conductive layer 441 is embedded in the second gate trench 439 across the second gate insulating layer 440. Specifically, the second gate conductive layer 441 is embedded in a recessed space that is defined by the second gate insulating layer 440 in the second gate trench 439. The second gate conductive layer 441 may contain a conductive polysilicon.

Referring to FIGS. 15 to 19, the FET structure 435 includes a first trench gate structure 36 formed on the first principal surface 3. The FET structure 435 is defined between the adjacent first trench gate structures 36 (between the adjacent first gate trenches 39). The emitter trench structures 73 extending in a band shape along the second direction Y are formed on both sides of the FET structure 435. In this preferred embodiment, the emitter trench structures 73 are formed not only on both sides of the FET structure 435 but also in the central portion of the FET structure 435 in the first direction X.

The emitter trench structure 73 is formed on the first principal surface 3. In the example of FIG. 15, two emitter trench structures 73 are formed between the adjacent first trench gate structures 36. These two emitter trench structures 73 sandwich one second trench gate structure 436 in the first direction X. That is, one emitter trench structure 73 is formed between the first trench gate structure 36 and the second trench gate structure 436 adjacent to each other.

Referring to FIGS. 18 and 19, the FET structure 435 further includes a plurality of p-type body regions 45 formed in the surface layer portion of the first principal surface 3, an n⁺-type carrier storage region 47 formed in a region on the second principal surface 4 side with respect to the body region 45, a plurality of n⁺-type emitter regions 46 formed in the first principal surface 3, and a plurality of p⁺-type contact regions 50 formed in the first principal surface 3.

Referring to FIGS. 16 to 19, the emitter region 46 and the contact region 50 are formed in a region between the first trench gate structure 36 and the emitter trench structure 73. A channel of the IGBT is formed in a region between the emitter region 46 and the carrier storage region 47 in the body region 45. That is, the channel of the IGBT is formed in the region between the first trench gate structure 36 and the emitter trench structure 73. In other words, the channel of the IGBT is formed in a region on both sides (both sides in the first direction X) of the first trench gate structure 36. The on/off of the channel is controlled by a gate signal applied to the first gate conductive layer 41 of the first trench gate structure 36.

The emitter region 46 and the contact region 50 are not formed in a region between the second trench gate structure 436 and the emitter trench structure 73. In the region between the second trench gate structure 436 and the emitter trench structure 73, the body region 45 is exposed to the first principal surface 3. Since the emitter region 46 is not formed, no channel is formed in the region between the second trench gate structure 436 and the emitter trench structure 73. That is, regions on both sides (both sides in the first direction X) of the second trench gate structure 436 have a structure in which no channel is formed. Therefore, the second trench gate structure 436 may be referred to as a dummy gate trench structure.

With reference to FIGS. 16, 18, and 19, attention is paid to the FET structure 435 included in the near-boundary region 8A in the IGBT region 8. Among the plurality of FET structures (unit cells) 435, the FET structure closest to the diode region 9 is referred to as a first FET structure (first unit cell) 435A, and the FET structure second closest to the diode region 9 is referred to as a second FET structure 435B. In this preferred embodiment, the FET structure 435 farther from the diode region 9 than the second FET structure 435B has the same structure as the second FET structure 435B.

Referring to FIG. 17, the FET structure 435 formed in the central portion 8M of the IGBT region 8 is referred to as a central FET structure (second unit cell) 435M. The central FET structure 435M is the FET structure 435 far from the diode region 9. The central FET structure 435M has the same configuration as the second FET structure 435B.

Referring to FIGS. 16 and 17, among the plurality of FET structures 435 included in the IGBT region 8, the predetermined FET structure (first FET structure 435A) included in the near-boundary region 8A has a smaller area (planar area) of the emitter region 46 and a larger area (planar area) of the contact region 50 than the central FET structure 435M in the central portion 8M of the IGBT region 8.

In the examples of FIGS. 16 and 17, the area of the emitter region 46 formed in the first FET structure 435A is smaller than the area of the emitter region 46 formed in the central FET structure 435M. Specifically, the area of the emitter region 46 formed in the first FET structure 435A is 50% (½ times) of the area of the emitter region 46 formed in the central FET structure 435M.

In other words, the area of the contact region 50 formed in the first FET structure 435A is larger than the planar area of the contact region 50 formed in the central FET structure 435M. Specifically, the planar area of the contact region 50 formed in the first FET structure 435A is 150% of the planar area of the contact region 50 formed in the central FET structure 435M.

An interval WF (see FIG. 16) between the emitter regions 46 adjacent in the second direction Y in the first FET structure 435A is larger than an interval WG (see FIG. 17) between the emitter regions 46 adjacent in the second direction Y in the central FET structure 435M.

As described above, in this preferred embodiment, the area of the emitter region 46 formed in the first FET structure 435A is smaller than the area of the emitter region 46 formed in the central FET structure 435M. Therefore, an area ratio of the emitter region 46 included in the first principal surface 3 of the near-boundary region 8A (the area of the emitter region 46/the entire area of the near-boundary region 8A) is smaller than an area ratio of the emitter region 46 included in the first principal surface 3 of the central portion 8M (the area of the emitter region 46/the entire area of the central portion 8M). Therefore, the area ratio of the emitter region 46 included in the first principal surface 3 of the near-boundary region 8A is smaller than the area ratio of the emitter region 46 included in the first principal surface 3 of the central portion 8M. Therefore, the number of parasitic transistors (the number of npn transistors) in the near-boundary region 8A can be reduced. By reducing an area ratio of the emitter region 46 in the near-boundary region 8A, it is possible to suppress the snapback phenomenon in the semiconductor device 401 while suppressing the deterioration of the forward voltage.

In the fourth preferred embodiment, the area of the emitter region 46 formed in the first FET structure 435A may be less than 50% (less than ½ times) of the area of the emitter region 46 formed in the central FET structure 435M. Further, the area of the emitter region 46 formed in the first FET structure 435A may be more than 50% and less than 100% (more than ½ times) of the area of the emitter region 46 formed in the central FET structure 435M.

In the fourth preferred embodiment, as long as the FET structure 435 is included in the near-boundary region 8A, the FET structure 435 other than the first FET structure 435A may be included in the FET structure (first unit cell) having a small area (planar area) of the emitter region 46. Specifically, in addition to the first FET structure 435A, the second FET structure 435B may be included in an FET structure having a small area (planar area) of the emitter region 46. Further, the FET structure 435 farther from the diode region 9 than the second FET structure 435B may be included in the FET structure (first unit cell) having a smaller area (planar area) of the emitter region 46.

In addition, the fourth preferred embodiment illustrated in FIGS. 15 to 19 may be combined with the semiconductor device 201 according to the second preferred embodiment. The fourth preferred embodiment illustrated in FIGS. 15 to 19 may be combined with the semiconductor device 301 according to the third preferred embodiment.

Preferred embodiments of the present disclosure can be implemented in still other modes.

In the examples of FIGS. 8 to 10, the emitter plug electrode 91 is formed in all the regions defined by the adjacent first trench gate structures 36 and emitter trench structures 73 in the first principal surface 3, but the emitter plug electrode 91 may be formed only in a partial region.

In each of the above-described embodiments, the semiconductor layer 2 may have a laminated structure including a p-type semiconductor substrate and an n⁻-type epitaxial layer formed on the semiconductor substrate, instead of the n-type semiconductor substrate 31. In this case, the p-type semiconductor substrate corresponds to the collector region 34. The n⁻-type epitaxial layer corresponds to the drift region 30.

The p-type semiconductor substrate may be made of silicon. The n′-type epitaxial layer may be made of silicon. The n-type epitaxial layer is formed by epitaxially growing silicon from the principal surface of the p-type semiconductor substrate.

In each of the preferred embodiments described above, a structure with which the conductivity types of the respective semiconductor portions are inverted may be adopted. That is, the p-type portion may be formed into an n-type, and the n-type portion may be formed into a p-type.

The features indicated below can be extracted from the present description and the drawings.

### APPENDIX 1-1

A semiconductor device (1, 201, 301, 401), including:
a semiconductor layer (2) having a first principal surface (3) and a second principal surface (4) opposite to the first principal surface (3);
an IGBT region (8) formed in the semiconductor layer (2);
a diode region (9) formed in the semiconductor layer (2) and adjacent to the IGBT region (8) in a first direction (X);
a plurality of gate trenches (39, 439) formed in the IGBT region (8) and extending in a second direction (Y) intersecting the first direction (X);
a gate conductive layer (41, 441) embedded in the gate trench (39,439) through a gate insulating layer (40,440);
a unit cell (35,435) defined between two of the gate trenches (39) formed at an interval in the first direction; and
an emitter region (46) formed on the first principal surface (3) of each of the unit cells (35,435),
wherein an area of the emitter region (46) formed in a first unit cell (35A, 35B, 435A) relatively close to the diode region (9) is smaller than an area of the emitter region (46) formed in a second unit cell (35M, 435M) farther from the diode region (9) than the first unit cell (35A, 35B, 435A).

According to this configuration, in the first principal surface (3), the area of the emitter region (46) formed in the first unit cell (35A, 35B, 435A) relatively closer to the diode region (9) is smaller than the area of the emitter region (46) formed in the second unit cell (35M, 435M) farther from the diode region (9) than the first unit cell (35A, 35B, 435A). Therefore, the number of parasitic transistors in the first unit cell (35A, 35B, 435A) can be made smaller than that in the second unit cell (35M, 435M). Thus, a snapback phenomenon can be suppressed in the semiconductor device (1, 201, 301, 401).

### APPENDIX 1-2

The semiconductor device (1, 201, 301, 401) according to Appendix 1-1, wherein the first unit cell (35A, 435A) is a unit cell (35A, 435A) closest to the diode region (9) among the plurality of unit cells (35, 435).

### APPENDIX 1-3

The semiconductor device (1,201,301,401) according to Appendix 1-1 or Appendix 1-2, wherein an area of the emitter region (46) formed in the first unit cell (35A, 35B, 435A) is ½ times or less an area of the emitter region (46) formed in the second unit cell (35M, 435M).

### APPENDIX 1-4

The semiconductor device (1,201,301,401) according to Appendix 1-1 or Appendix 1-2, wherein an area of the emitter region (46) formed in the first unit cell (35A, 35B, 435A) is larger than ½ times an area of the emitter region (46) formed in the second unit cell (35M, 435M).

### APPENDIX 1-5

The semiconductor device (1, 201, 301, 401) according to any one of Appendix 1-1 to Appendix 1-4, wherein, in each of the unit cells (35, 435), a plurality of the emitter regions (46) are formed at intervals in the second direction (Y), and an interval (WB) between the emitter regions (46) adjacent to each other in the second direction (Y) in the first unit cell (35A, 35B, 435A) is larger than an interval (WC) between the emitter regions (46) adjacent to each other in the second direction (Y) in the second unit cell (35M, 435M).

### APPENDIX 1-6

The semiconductor device (1, 201, 301, 401) according to any one of Appendix 1-1 to Appendix 1-5, wherein the emitter region (46) is of a first conductivity type,
the IGBT region (8) further includes a drift region (30) of a first conductivity type formed in the semiconductor layer (2), a body region (45) of a second conductivity type formed in a surface layer portion of the drift region (30), and a contact region (50) of a second conductivity type formed in the first principal surface (3) and having a higher impurity concentration than the body region (45), and
an area of the contact region (50) formed in the first unit cell (35A, 35B, 435A) is larger than an area of the contact region (50) formed in the second unit cell (35M, 435M).

### APPENDIX 1-7

The semiconductor device (1, 201, 301) according to any one of Appendix 1-1 to Appendix 1-6, wherein a first emitter array (L1) including a plurality of the emitter regions (46) arranged along the first direction (X) and a second emitter array (L2) including a plurality of the emitter regions (46) arranged along the first direction (X) in a region spaced apart in the first emitter array (L1) in the second direction (Y) are formed on the first principal surface (3) of the IGBT region (8), and
an end portion (E2) on the diode region side in the second emitter array (L2) is farther from the diode region (9) than an end portion (E1) on the diode region side in the first emitter array (L1).

### APPENDIX 1-8

The semiconductor device (1,201,301) according to Appendix 1-7, wherein the emitter region (46) is of a first conductivity type, and
the IGBT region (8) further includes a drift region (30) of a first conductivity type formed in the semiconductor layer (2), a body region (45) of a second conductivity type formed in a surface layer portion of the drift region (30), and a contact region (50) of a second conductivity type having a higher impurity concentration than the body region (45), and
the contact region (50) includes a region formed such as to be sandwiched between the second emitter array (L2) and the diode region (9) on the first principal surface (3).

### APPENDIX 1-9

The semiconductor device (1,201,301) according to Appendix 1-8, wherein the contact region (50) further includes a region formed between the first emitter array (L1) and the second emitter array (L2) on the first principal surface (3).

### APPENDIX 1-10

The semiconductor device (201, 301) according to Appendix 1-7, wherein the emitter region (46) is of a first conductivity type
the IGBT region (8) further includes a drift region (30) of a first conductivity type formed in the semiconductor layer (2), a body region (45) of a second conductivity type formed in a surface layer portion of the drift region (30), and a contact region (50) of a second conductivity type having a higher impurity concentration than the body region (45),
the contact region (50) includes a region formed between the first emitter array (L1) and the second emitter array (L2) on the first principal surface (3), and
the body region (45) is sandwiched between the second emitter array (L2) and the diode region (9) on the first principal surface (3).

### APPENDIX 1-11

The semiconductor device (201,301) according to Appendix 1-10, further including:
an emitter terminal electrode (13); and
an emitter plug electrode (91) formed such as to extend in the second direction (Y) on the first principal surface (3) and electrically connecting the emitter terminal electrode (13) and the emitter region (46),
wherein the emitter plug electrode (91) is divided in a region between the second emitter array (L2) and the diode region (9) on the first principal surface (3).

### APPENDIX 1-12

The semiconductor device (1, 201, 301) according to any one of Appendix 1-7 to Appendix 1-11, wherein the first emitter array (L1) and the second emitter array (L2) include a plurality of first emitter arrays (L1) and a plurality of second emitter arrays (L2), respectively, and
the first emitter array (L1) and the second emitter array (L2) are arranged in the second direction (Y) in a constant repetitive pattern.

### APPENDIX 1-13

The semiconductor device (1, 201, 301) according to Appendix 1-12, wherein the first emitter array (L1) and the second emitter array (L2) are alternately arranged in the second direction (Y).

### APPENDIX 1-14

The semiconductor device (1,201,301) according to Appendix 1-12 or Appendix 1-13, wherein in the plurality of second emitter arrays (L2), a distance (WE) between an end portion (E2) on the diode region side and the diode region (9) is the same.

### APPENDIX 1-15

The semiconductor device (201, 301, 401) according to any one of Appendix 1-1 to Appendix 1-14, wherein the IGBT region (8) includes a collector region (34) of a second conductivity type formed in a surface layer portion of the second principal surface (4), and the collector region (34) includes a lead-out region (282) extended toward the diode region (9) across a boundary (72) between the IGBT region (8) and the diode region (9).

### APPENDIX 1-16

The semiconductor device (1,201,301) according to any one of Appendix 1-1 to Appendix 1-15, wherein the unit cell (35) is defined between the adjacent gate trenches (39).

1. A semiconductor device, comprising:
a semiconductor layer having a first principal surface and a second principal surface opposite to the first principal surface;
an IGBT region formed in the semiconductor layer;
a diode region formed in the semiconductor layer and adjacent to the IGBT region in a first direction;
a plurality of gate trenches formed in the IGBT region and extending in a second direction intersecting the first direction;
a gate conductive layer embedded in the gate trench through a gate insulating layer;
a unit cell defined between the gate trenches formed at intervals in the first direction; and
an emitter region formed on the first principal surface of each of the unit cells,
wherein an area of the emitter region formed in a first unit cell relatively close to the diode region is smaller than an area of the emitter region formed in a second unit cell farther from the diode region than the first unit cell.

2. The semiconductor device according to claim 1, wherein the first unit cell is a unit cell closest to the diode region among the plurality of unit cells.

3. The semiconductor device according to claim 1, wherein an area of the emitter region formed in the first unit cell is ½ times or less an area of the emitter region formed in the second unit cell.

4. The semiconductor device according to claim 1, wherein an area of the emitter region formed in the first unit cell is larger than ½ times an area of the emitter region formed in the second unit cell.

5. The semiconductor device according to claim 1, wherein in each of the unit cells, a plurality of the emitter regions are formed at intervals in the second direction, and
an interval between the emitter regions adjacent to each other in the second direction in the first unit cell is larger than an interval between the emitter regions adjacent to each other in the second direction in the second unit cell.

6. The semiconductor device according to claim 1, wherein
the emitter region is of a first conductivity type,
the IGBT region further includes a drift region of a first conductivity type formed in the semiconductor layer, a body region of a second conductivity type formed in a surface layer portion of the drift region, and a contact region of a second conductivity type formed on the first principal surface and having a higher impurity concentration than the body region, and
an area of the contact region formed in the first unit cell is larger than an area of the contact region formed in the second unit cell.

7. The semiconductor device according to claim 1, wherein
a first emitter array including a plurality of the emitter regions arranged along the first direction and a second emitter array including a plurality of the emitter regions arranged along the first direction in a region spaced apart from the first emitter array in the second direction are formed on the first principal surface of the IGBT region, and
an end portion on the diode region side in the second emitter array is farther from the diode region than an end portion on the diode region side in the first emitter array.

8. The semiconductor device according to claim 7, wherein
the emitter region is of a first conductivity type,
the IGBT region further includes a drift region of a first conductivity type formed in the semiconductor layer, a body region of a second conductivity type formed in a surface layer portion of the drift region, and a contact region of a second conductivity type having a higher impurity concentration than the body region, and
the contact region includes a region formed such as to be sandwiched between the second emitter array and the diode region on the first principal surface.

9. The semiconductor device according to claim 8, wherein the contact region further includes a region formed between the first emitter array and the second emitter array on the first principal surface.

10. The semiconductor device according to claim 7, wherein
the emitter region is of a first conductivity type,
the IGBT region further includes a drift region of a first conductivity type formed in the semiconductor layer, a body region of a second conductivity type formed in a surface layer portion of the drift region, and a contact region of a second conductivity type having a higher impurity concentration than the body region, and
the contact region includes a region formed between the first emitter array and the second emitter array on the first principal surface, and
the body region is sandwiched between the second emitter array and the diode region on the first principal surface.

11. The semiconductor device according to claim 10, further comprising:
an emitter terminal electrode; and
an emitter plug electrode formed such as to extend in the second direction on the first principal surface and electrically connecting the emitter terminal electrode and the emitter region,
wherein the emitter plug electrode is divided in a region between the second emitter array and the diode region on the first principal surface.

12. The semiconductor device according to claim 7, wherein
the first emitter array and the second emitter array include a plurality of first emitter arrays and a plurality of second emitter arrays, respectively, and
the first emitter array and the second emitter array are arranged in the second direction in a constant repetitive pattern.

13. The semiconductor device according to claim 12, wherein the first emitter array and the second emitter array are alternately arranged in the second direction.

14. The semiconductor device according to claim 12, wherein in the plurality of second emitter arrays, a distance between an end portion on the diode region side and the diode region is the same.

15. The semiconductor device according to claim 1, wherein the IGBT region includes a collector region of a second conductivity type formed in a surface layer portion of the second principal surface, and
the collector region includes a lead-out region extended toward the diode region across a boundary between the IGBT region and the diode region.
